(19) United States
(12) Patent Application Publication
(10) Pub. No.: US 2004/0153926 A1
(43) Pub. Date: Aug. 5, 2004

(54) Method and apparatus for testing asynchronous set/reset faults in a scan-based integrated circuit

(76) Inventors: Khader S. Abdel-Hafez, San Francisco, CA (US); Laung-Terng Wang, Sunnyvale, CA (US); Augusli Kifli, Hsinchu (TW); Fei-Sheng Hsu, Hsinchu (TW); Xiaoqing Wen, Sunnyvale, CA (US); Meng-Chyi Lin, Taoyuan (TW); Hsin-Po Wang, Hsinchu (TW)

Correspondence Address: Law Office of Jim Zegeer, Suite 108, 801 North Pitt Street, Alexandria, VA, 22314, US

(21) Appl. No.: 10/691,966

(22) Filed: Oct. 24, 2003

Related U.S. Application Data
(60) Provisional application No. 60/422,117, filed on Oct. 30, 2002.

(51) Int. Cl. G01R 31/28

(52) U.S. Cl. 714/726

(57) ABSTRACT

A method and apparatus to test data and set/reset faults in a scan-based integrated circuit in a selected scan-test mode or self-test mode. The scan-based integrated circuit contains multiple scan chains, each scan chain comprising multiple scan cells coupled in series. The method comprises shifting in a plurality of predetermined stimuli during scan-test or pseudo-random stimuli during self-test to the scan-based integrated circuit, using a set/reset enable (SR_EN) signal 383 and a scan enable (SE) signal 382 to capture faults to each scan cell, and shifting out the test responses for comparison or compaction. The apparatus or set/reset controller 375 further comprises using the set/reset enable (SR_EN) signal 383 and scan enable (SE) signal 382 to selectively propagate data faults or set/reset faults to the scan cells in the integrated circuit. Computer-aided design (CAD) methods are then proposed to automatically repair all asynchronous set/reset signals in the scan-based integrated circuit and generate test patterns comprising stimuli and test responses for verifying the correctness of the repaired scan-based integrated circuit during scan-test or self-test.

### RELATED APPLICATION DATA

This application claims the benefit of U.S. Provisional Application No. 60/422,117 filed Oct. 30, 2002, titled “Method and Apparatus for Testing Asynchronous Set/Reset Faults in a Scan-Based Integrated Circuit”, which is hereby incorporated by reference.

### TECHNICAL FIELD

The present invention generally relates to the field of logic design and test using design-for-test (DFT) techniques. Specifically, the present invention relates to the field of testing asynchronous set/reset faults in integrated circuits by using scan test techniques.

### BACKGROUND

Design methodologies for complex integrated circuits (IC) have evolved to keep pace with the advances in process technologies. The growing number of transistors that can be integrated onto a single device has resulted in shifting the design process to higher levels of abstraction. Hardware description languages (HDLs) have become widely used for describing the behavior of a circuit at various levels of abstraction. Currently, the most commonly used methodology for integrated circuit design is to use Verilog or VHDL HDL to describe a circuit at the register-transfer level (RTL) and to use computer-aided design (CAD) software called a logic synthesis tool to convert the HDL design description into a functionally-equivalent technology-dependent gate-level netlist, while taking into account user constraints related to timing, power, area, etc. The netlist generated by this synthesis process is later taken through a back-end process in order to create a manufacturable representation of the design.

Each manufactured integrated circuit must be tested in order to verify its structural correctness. With the ever-increasing scale and complexity of integrated circuits, the goal of achieving high test-quality at a reasonable cost is becoming extremely difficult. Therefore, improving the inherent testability of an integrated circuit is imperative in order to realize this goal.

Numerous techniques have been developed for improving the testability of an integrated circuit. These techniques are collectively referred to as design-for-test (DFT) techniques.

Among the various DFT techniques, scan-based design has emerged as the most widely used DFT methodology, encompassing the de-facto scan-test methodology using Scan/ATPG (automatic test pattern generation) as well as the self-test methodology using Logic BIST (built-in self-test).

In a scan-based integrated circuit, the original memory elements, comprising flip-flops and/or latches, are replaced with scan-equivalent storage elements, called scan cells. These scan cells are allowed to select one of two possible data sources depending on the state of a selected scan enable (SE) signal. When SE is set to logic value 0, the normal data input port is selected. When SE is set to logic value 1, the scan input port is selected. The scan input ports and scan output ports of all scan cells are stitched together in a way so that the scan cells are reconfigured as one or more shift registers called scan chains. These scan chains are either accessed internally during self-test or through external scan input ports and scan output ports during scan-test.

Three operations are used to test a scan-based integrated circuit. These operations are shift-in, capture and shift-out. During the shift-in operation, the scan enable (SE) signal of all scan cells is set to logic value 1. A stimulus is shifted in through the scan chains to initialize the state of all scan cells present in the integrated circuit. Next, during the capture operation, the scan enable (SE) signal is set to logic value 0. Clocks are applied to all scan cells capturing the circuit's response to the stimulus shifted in by the previous operation through the functional logic. Finally, during the shift-out operation, the scan enable (SE) signal is once again set to logic value 1. The captured test response is shifted out through the scan chains. This test response can be compared directly to a predetermined expected response, or compacted into a signature using a compactor such as a multiple-input signature register (MISR) for later comparison. Typically, the shift-in and shift-out operations occur simultaneously as a single shift operation so that a new stimulus is loaded into the scan chains while the previous captured test response is being shifted out. The test is conducted by repetitively applying a predetermined number of test patterns, each consisting of the simultaneous shift-in/shift-out and capture operations.

In order for the scan cells to operate as a shift register during the shift-in or shift-out operation, it is necessary to disable the set and reset signals of all scan cells in order to prevent these signals from corrupting the data being shifted in or out through the scan chains. This is easily accomplished in cases where the set and reset signals are controlled externally by forcing these external signals into an inactive state. In situations where this is not the case, a set/reset scan-based DFT design-rule violation is said to exist in the circuit. These set/reset violations, as well as other types of DFT design-rule violations, must be repaired in order to be able to use the scan chains to test a scan-based integrated circuit.

Repairing DFT design-rule violations in a scan-based integrated circuit involves modifying the design to add additional circuitry and/or external signals that are active only during scan-test or self-test. Current methods for repairing asynchronous set/reset violations can result in race conditions and glitches, or fault coverage loss related to the faults present in the functional circuitry driving the set/reset ports of a scan cell. The following is a summary of the four major prior-art solutions used to fix asynchronous set/reset DFT design-rule violations:

The first prior-art solution (prior-art #1, FIG. 2B) uses a test enable (TE) signal and an external set/reset signal to control the asynchronous set/reset ports of all scan cells for the complete duration of scan-test or self-test. This solution repairs the asynchronous set/reset violations by adding a multiplexor that is controlled by the test enable (TE) signal to select either the original functional asynchronous set/reset path in functional mode, or the external set/reset signal in scan-test or self-test mode. In order to disable the asynchronous set/reset ports during the shift operation, the external set/reset signal is set to an inactive state allowing the scan chains to operate correctly as a shift register. During the capture operation, the external set/reset signal is toggled to capture data through the asynchronous set/reset ports of the scan cells in order to detect the faults occurring on these ports. Since the functional set/reset logic is never selected during scan-test or self-test, the faults associated with this logic cannot be detected using this scheme. This results in a fault coverage loss that can be significant, depending on the number of faults associated with the functional asynchronous set/reset circuitry present in the circuit, which in turn depends on the size of the set/reset circuitry driving the asynchronous set/reset ports of all scan cells in the circuit.

The second prior-art solution (prior-art #2, FIG. 2C) uses a test enable (TE) signal to disable the asynchronous set/reset ports of all scan cells for the complete duration of scan-test or self-test. This solution repairs the asynchronous set/reset violations by adding an AND gate and an inverter to force all asynchronous set/reset ports into an inactive state using the test enable (TE) signal in scan-test or self-test mode, while allowing the functional set/reset signals to drive the asynchronous set/reset ports in functional mode. While this solution has a lower overhead compared to prior-art #1, it results in greater fault coverage loss since it cannot be used to detect the faults located at the set/reset ports of the scan cells present in the circuit.

The third prior-art solution (prior-art #3, FIG. 2D) uses a scan enable (SE) signal to disable the asynchronous set/reset ports of all scan cells during the shift operation for the complete duration of scan-test or self-test. This solution repairs the asynchronous set/reset violations by adding an AND gate and an inverter to force all asynchronous set/reset ports into an inactive state using the scan enable (SE) signal in scan-test or self-test mode, while allowing the functional set/reset signals to drive the asynchronous set/reset ports during the capture operation as well as during normal operation. This guarantees that the asynchronous set/reset ports of all scan cells are disabled during the shift operation allowing the scan chains to operate correctly as a shift register. The advantage of this solution is that the faults present in the functional circuitry driving the asynchronous set/reset ports of all scan cells can now be propagated and tested during the capture operation resulting in no fault coverage loss as compared to prior-art solutions #1 and #2. In practice however, problems occur when using this solution due to the race condition between the data and set/reset ports that occurs during the capture cycle. This can often result in an unreliable state being captured into the scan cells, followed by pattern mismatches during comparison or compaction, thus invalidating the test.

The fourth prior-art solution (prior-art #4, FIG. 2E) uses an external set/reset enable (ESR_EN) signal to disable the asynchronous set/reset ports of all scan cells during scan-test. This solution repairs the asynchronous set/reset violations by adding a multiplexor gate.

During the shift operation, the external set/reset enable (ESR_EN) signal is disabled to guarantee that all asynchronous set/reset ports of all scan cells are disabled allowing all scan chains to operate correctly as a shift register. During the capture operation, two options are possible. In one option, ESR_EN is set to allow the functional set/reset signals to drive the asynchronous set/reset ports, while the clocks are disabled, to test the set/reset logic. In the other option, ESR_EN is used to force all asynchronous set/reset ports into an inactive state, while the clocks are used to test the faults on the data ports of the scan cells.

The advantage of this solution is that the faults present in the functional circuitry driving the asynchronous set/reset ports of all scan cells can now be propagated and tested during the capture operation resulting in no fault coverage loss as compared to prior-art solutions #1 and #2 and in a way that does not create the glitches associated with race conditions between the clock and the set/reset ports of the scan cell. Race conditions, due to ripple reset conditions where setting or resetting a set of scan cells creates an intermediate state forcing additional set of scan cells being set or reset unexpectedly, are solved by using the multiple ripple ESR_EN signals, thus, no glitches are possible.

However, this solution suffers from two problems. The first problem that the ESR_EN signals must be external pins makes it a difficult solution to implement for pad-limited solutions during scan-test. This might force the designer to choose between implementing this solution with a smaller number of scan chains and longer test time or abandoning this solution to allow for more scan chains. The other problem is with regards to implementing this solution in a self-test environment. Since the ESR_EN signals are not qualified with a scan enable (SE) signal, it is impossible to use this solution in a self-test environment without destroying the contents of the scan chains during shift, hence invalidating the test.

Therefore, there is a need for an improved asynchronous set/reset DFT design-rule violation repair technique comprising a method, apparatus, and a computer-aided design (CAD) system to ensure correct shift operations, detect asynchronous set/reset faults, and avoid race conditions and glitches that can be used for both scan-test and self-test. In addition, there is a need for a method and a computer-aided design (CAD) system for generating and/or fault simulating test patterns based on the improved technique, in order to test data and set/reset faults in a scan-based integrated circuit.

### SUMMARY

Accordingly, the first primary objective of the present invention is to provide an improved asynchronous set/reset DFT violation repair system to ensure correct shift operations and to detect asynchronous set/reset faults while avoiding race conditions and glitches during scan-test or self-test. This system comprises of a method and apparatus for guaranteeing correct shift operations by disabling the asynchronous set/reset ports of scan cells during the shift operation, while allowing the asynchronous set/reset faults to propagate and to be detected without race conditions and glitches during the capture operation. The present invention further comprises of a computer-aided design (CAD) system for RTL scan synthesis and/or gate-level circuit modification based on this method. The inputs to the CAD system are a set of RTL codes or a gate-level netlist modeled in HDL together with any required scan constraints.

The present invention uses a global scan enable (SE) signal, one or more global set/reset enable (SR_EN) signals, and some additional logic circuitry to achieve the stated objective. The scan enable (SE) signal controls the additional logic circuitry to disable the asynchronous set/reset ports of all scan cells during the shift operation. During the capture operation two separate methodologies are possible for testing the asynchronous set/reset faults.

In the first methodology, two sets of patterns are generated for the capture operation, one set of patterns where the SR_EN signal is permanently set to disable the asynchronous set/reset ports and the clocks are captured in order to test the faults on the data ports of the scan cells, and the other set of patterns where the SR_EN signal is set to enable the set/reset path with no capture clocks being applied, in order to test the faults on the asynchronous set/reset ports of the scan cells.

In the second methodology, both sets of patterns of the previous methodology are merged to create one set of test patterns where the SR_EN signal acts as a clock that is first disabled while the regular system clocks are applied to capture the faults on the data inputs of the scan cells and later toggled to enable the asynchronous set/reset faults to propagate and to be tested and then disabled in time for the next shift operation. In these two methodologies, since the SR_EN is always disabled when the clocks are being applied, no race conditions of glitches can occur, and since the SR_EN is enabled at some point to allow the asynchronous set/reset faults to propagate, we are guaranteed to be able to thoroughly test the asynchronous set/reset circuitry, hence overcoming all the shortcomings of prior-art solutions #1, #2 and #3.

Ripple reset glitches where simultaneously setting and/or resetting a set of scan cells causes the circuit to go through intermediate states that generate indeterministic reset glitches on other scan cells are solved by using multiple SR_EN signals to break the ripple reset cycle. Since the SR_EN signals of the present invention can either be generated internally or applied externally this does not result in any additional requirement regarding the number of external pins needed for scan-test. Furthermore since scan enable is used to disable the set/reset ports during the shift operation this solution can easily adapted for either scan-test or self-test, hence overcoming all the shortcomings of prior-art solution #4. The present invention covers the mentioned asynchronous set/reset DFT design-rule violation repair at RTL, gate-level or any other level of abstraction during the design process.

The second primary objective of the present invention is to provide an improved system for improving fault coverage. This system comprises a method and a computer-aided design (CAD) system for generating and/or fault simulating test patterns to test data faults and set/reset faults in a scan-based integrated circuit, where the asynchronous set/reset violations have been repaired by the asynchronous set/reset violation repair method, in accordance with the present invention.

The asynchronous set/reset violation repair method and the test pattern generation and/or fault simulation method for a scan-based integrated circuit obtained after such repair, in accordance with the present invention, are summarized as follows:

(1) Asynchronous Set/Reset Violation Identification

Generally, the asynchronous set/reset signal of a scan cell is generated by a set/reset circuitry driven by primary inputs, bi-directional primary inputs, scan inputs, and the outputs of scan cells. Its identification as an asynchronous set/reset DFT design-rule violation using testability analysis can be made at RTL, gate-level, or any other level of abstraction during the design process.

Asynchronous set/reset violations can be classified under four different categories for identification purposes: Sequentially-Gated Set/Reset, Combinationally-Gated Set/Reset, Generated Set/Reset, and Destructive Set/Reset. In a Sequentially-Gated Set/Reset violation, the set/reset signal can be traced back to a specific set/reset source, such as an external set/reset signal, that is gated with the output of a memory element, such as a flip-flop or a latch. In a Combinationally-Gated Set/Reset violation, the set/reset signal can be traced back to a specific set/reset source that is gated with a primary input or the output of a combinational logic block driven by one or more primary inputs. In a Generated Set/Reset violation, the set/reset signal cannot be traced back to a specific set/reset source. In a Destructive Set/Reset violation, the set/reset signal is constantly forced into an active/destructive state by an internal hardwire.

(2) Asynchronous Set/Reset Violation Repair Circuitry

(2-1) Set/Reset Controller

If the asynchronous set/reset signal of a scan cell is identified as an asynchronous set/reset DFT design-rule violation of any of the four types mentioned in (1), the present invention adds a set/reset controller related to the set/reset circuitry and the set/reset ports of the scan cell either automatically or interactively. A set/reset controller is controlled by a scan enable (SE) signal and a set/reset enable (SR_EN) signal. A set/reset controller further comprises of a shift controller and a capture controller.

(2-2) Shift Controller

A shift controller comprises circuitry that uses a scan enable (SE) signal to disable the asynchronous set/reset ports of a scan cell, in order to avoid destroying data held by the scan cell during the shift operation. A shift controller can be embedded as part of the set/reset circuitry of a scan cell or placed between the set/reset circuitry and its corresponding scan cell. Furthermore, a scan enable (SE) signal can be generated in an integrated circuit or provided as an external input signal to the device.

(2-3) Capture Controller

A capture controller comprises circuitry that uses a set/reset enable (SR_EN) signal to selectively allow the propagation of faults in the set/reset circuitry of a scan cell to the asynchronous set/reset ports of the scan cell during the capture operation. In order for race conditions not to occur, this must be done at a time when all capture clocks are inactive, to avoid the hazardous, simultaneous propagation of signals through the set/reset and data inputs of the scan cells. A capture controller can be embedded as part of the set/reset circuitry of a scan cell or placed between the set/reset circuitry and the corresponding scan cell. Furthermore, a set/reset enable (SR_EN) can be generated in an integrated circuit or provided as an external input signal to the device.

(3) Asynchronous Set/Reset Violation Repair Operation

A possible operation of a set/reset controller is as follows: During the shift operation, the scan enable (SE) signal is set to logic value 1, forcing the shift controller to set the asynchronous set/reset ports of all scan cells to the inactive state, preventing the shift in data from being destroyed. Once the shift operation is completed, the circuit enters the capture operation where the scan enable (SE) signal is set to logic value 0. During the first stage of the capture operation, the set/reset enable (SR_EN) signal is set to logic value 0, forcing the asynchronous set/reset ports of all scan cells to remain disabled and the clocks are applied to capture the fault effects propagated to the data ports into the scan cells. During the second stage of the capture operation, all clocks are disabled and the set/reset enable (SR_EN) signal is set to logic value 1, enabling the propagation of the faults in the set/reset circuitry to the scan cells via the asynchronous set/reset ports. In this manner, the asynchronous set/reset faults of a scan cell can be detected without suffering from race conditions or glitchs.

The following table summarizes a possible implementation of a set/reset controller according to the present invention:

| TE | SE | SR_EN | Clock | Mode | Operation |
|---|---|---|---|---|---|
| 0 | X | X | Active | Functional | Normal |
| 1 | 1 | X | Active | Scan-Test or Self-Test | Shift |
| 1 | 0 | 0 | Active | Scan-Test or Self-Test | Capture |
| | | | | | (Data Faults) |
| 1 | 0 | 1 | Inactive | Scan-Test or Self-Test | Capture |
| | | | | | (Set/Reset Faults) |

(4) Test Pattern Generation for Data and Set/Reset Faults

Once all asynchronous set/reset violations in a scan-based integrated circuit are repaired, test pattern generation and/or fault simulation is performed on the repaired circuit in order to improve the fault coverage for set/reset as well as data faults. This method comprises the following computer-implemented steps:

(4-1) Compile the HDL (Hardware Description Language) Code Modeled at RTL (Register-transfer Level) or Gate-level That Represents the Repaird Scan-based Integrated Circuit into a Sequential Circuit Model.

(4-2) Specify Input Constraints on Clocks, the Set/Reset Enable (SR_EN) Signal, and the Scan Enable (SE) Signal of the Repaird Scan-based Integrated Circuit.

(4-3) Transform the Sequential Circuit Model into an Equivalent Combinational Circuit Model.

(4-4) Generate and/or Fault Simulate Test Patterns According to the Specified Input Constraints and the Combinational Circuit Model.

In summary, the present invention provides an improved asynchronous set/reset violation repair technique, comprising a method, apparatus, and a computer-aided design (CAD) system, to ensure correct shift operations and detect asynchronous set/reset faults while avoiding race conditions and glitches. In addition, the present invention provides a method and a computer-aided design (CAD) system for generating and/or fault simulating test patterns to test data and set/reset faults in a scan-based integrated circuit, where asynchronous set/reset DFT design-rule violations are repaired according to the present invention. As a result, all faults in the set/reset circuitry are detected using test patterns that are free of all race conditions and glitches, and a higher fault coverage is achieved.

### THE BRIEF DESCRIPTION OF DRAWINGS

The above and other objects, advantages and features of the invention will become more apparent when considered with the following specification and accompanying drawings wherein:

FIG. 1A shows an example integrated circuit design before scan synthesis is performed;

FIG. 1B shows the resulting design after scan synthesis is performed on the design shown in FIG. 1A;

FIG. 2A shows an example design with an asynchronous reset violation;

FIG. 2B shows the result of applying the prior-art #1 solution to repair the asynchronous reset violation shown in FIG. 2A;

FIG. 2C shows the result of applying the prior-art #2 solution to repair the asynchronous reset violation shown in FIG. 2A;

FIG. 2D shows the result of applying the prior-art #3 solution to repair the asynchronous reset violation shown in FIG. 2A;

FIG. 2E shows the result of applying the prior-art #4 solution to repair the asynchronous reset violation shown in FIG. 2A;

FIG. 3A shows a block diagram of two set/reset controllers in a design without any ripple structure, in accordance with the present invention;

FIG. 3B shows a block diagram of three set/reset controllers in a design with a two-stage ripple structure, in accordance with the present invention;

FIG. 3C shows an embodiment of a set/reset controller, in accordance with the present invention;

FIG. 4A shows a timing diagram for testing the design without any ripple structure shown in FIG. 3A, in accordance with the present invention, where both data faults and set/reset faults are detected during the same capture operation with non-overlapping single-capture clocks;

FIG. 4B shows a timing diagram for testing the design without any ripple structure shown in FIG. 3A, in accordance with the present invention, where both data faults and set/reset faults are detected during the same capture operation with overlapping single-capture clocks;

FIG. 4C shows a timing diagram for testing the design without any ripple structure shown in FIG. 3A, in accordance with the present invention, where both data faults and set/reset faults are detected -during the same capture operation with non-overlapping at-speed double-capture clocks;

FIG. 4D shows a timing diagram for testing the design without any ripple structure shown in FIG. 3A, in accordance with the present invention, where both data faults and set/reset faults are detected during the same capture operation with overlapping at-speed double-capture clocks;

FIG. 4E shows a timing diagram for testing the design without any ripple structure shown in FIG. 3A, in accordance with the present invention, where data faults and set/reset faults are detected during two capture operations with non-overlapping single-capture clocks;

FIG. 4F shows a timing diagram for testing the design without any ripple structure shown in FIG. 3A, in accordance with the present invention, where data faults and set/reset faults are detected during two capture operations with non-overlapping at-speed double-capture clocks;

FIG. 4G shows a timing diagram for testing the design with a two-stage ripple structure shown in FIG. 3B, in accordance with the present invention, where both data faults and set/reset faults are detected during the same capture operation with non-overlapping single-capture clocks;

FIG. 4H shows a timing diagram for testing the design with a two-stage ripple structure shown in FIG. 3B, in accordance with the present invention, where both data faults and set/reset faults are detected during the same capture operation with non-overlapping at-speed double-capture clocks;

FIG. 4I shows a timing diagram for testing the design with a two-stage ripple structure shown in FIG. 3B, in accordance with the present invention, where both data faults and set/reset faults are detected during two capture operations with non-overlapping single-capture clocks;

FIG. 4J shows a timing diagram for testing the design with a two-stage ripple structure shown in FIG. 3B, in accordance with the present invention, where both data faults and set/reset faults are detected during two capture operations with non-overlapping at-speed double-capture clocks;

FIG. 5A shows an example set of RTL (register-transfer level) Verilog codes before and after a sequentially-gated reset violation and a combinationally-gated reset violation are repaired, in accordance with the present invention;

FIG. 5B shows an example set of RTL (register-transfer level) Verilog codes before and after a generated reset violation and a destructive reset violation are repaired, in accordance with the present invention;

FIG. 5C shows the gate-level circuit model corresponding to the original RTL (register-transfer level) code shown in FIG. 5A;

FIG. 5D shows the gate-level circuit model obtained after the sequentially-gated reset violation and the combinationally-gated reset violation shown in FIG. 5C are repaired, in accordance with the present invention;

FIG. 5E shows the gate-level circuit model corresponding to the original RTL (register-transfer level) code shown in FIG. 5B;

FIG. 5F shows the gate-level circuit model after the generated reset violation and the destructive reset violation shown in FIG. 5E are repaired, in accordance with the present invention;

FIG. 6 shows a flow diagram of the method for repairing asynchronous set/reset violations at either RTL (register-transfer level) or gate-level, in accordance with the present invention;

FIG. 7A shows a flow diagram of the method for generating test patterns for data faults and set/reset faults in scan-test mode, in accordance with the present invention;

FIG. 7B shows a flow diagram of the method for generating test patterns for data faults and set/reset faults in self-test mode, in accordance with the present invention; and

FIG. 8 shows an example electronic design automation system in which the method for repairing asynchronous set/reset violations at either RTL (register-transfer level) or gate-level and the method of generating test patterns for data faults and set/reset faults, in accordance with the present invention, may be implemented.

### DETAILED DESCRIPTION OF THE INVENTION

The following description is presently contemplated as the best mode of carrying out the present invention. This description is not to be taken in a limiting sense but is made merely for the purpose of describing the principles of the invention. The scope of the invention should be determined by referring to the appended claims.

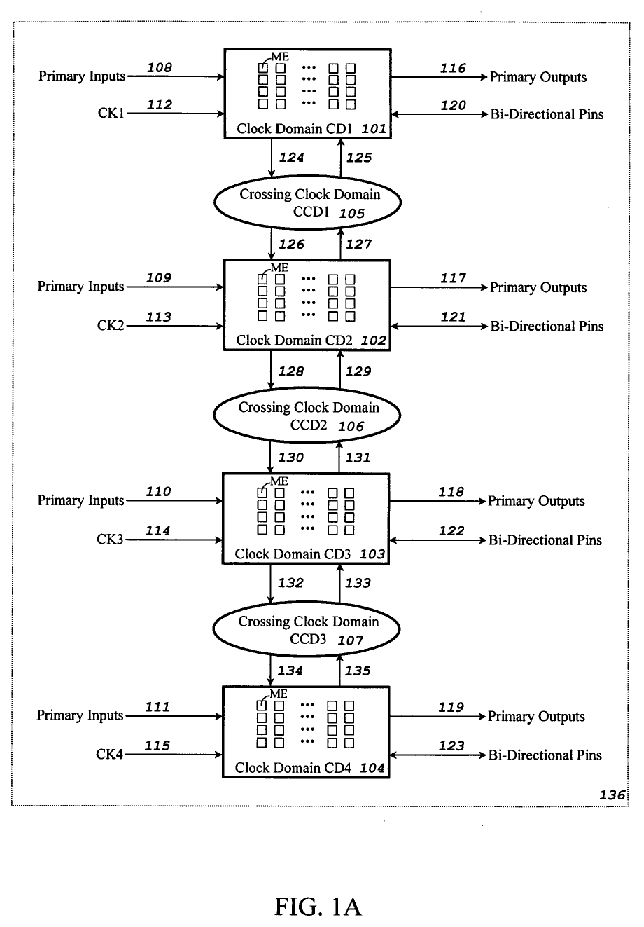

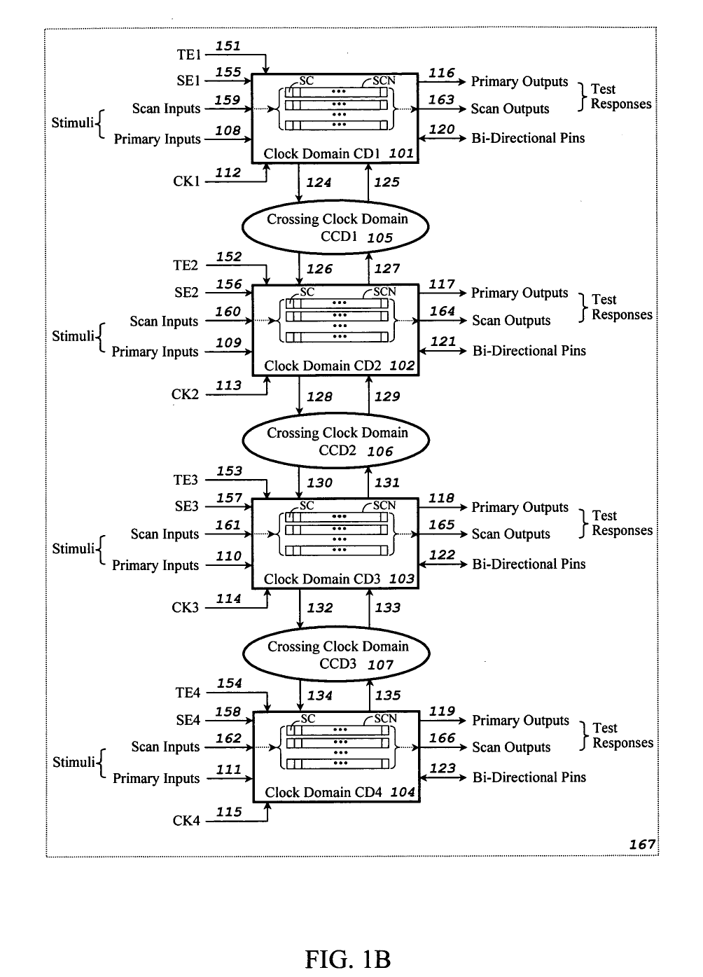

FIG. 1A shows an example integrated circuit design 136 before scan synthesis is performed. The design 136 has four clock domains CD1 101 to CD4 104, three crossing clock-domain logic blocks CCD1 105 to CCD3 107, primary inputs 108 to 111, primary outputs 116 to 119, and bi-directional pins 120 to 123. In addition, it has four system clocks CK1 112 to CK4 115. Furthermore, memory elements ME exist in four clock domains CD1 101 to CD4 104.

FIG. 1B shows the resulting design 167 after scan synthesis is performed on the design 136 shown in FIG. 1A. After scan synthesis is performed, all or part of original memory elements ME are replaced with scan cells SC. In addition, the scan cells SC are stitched into one or more scan chains SCN, which can be accessed by scan inputs 159 to 162 and scan outputs 163 to 166. Note that a scan cell can be a multiplexed-type D flip-flop, a two-port D flip-flop, or a LSSD (level-sensitive scan design) SRL (shift register latch). A scan cell can accept an input value either from its data input port connected to a functional logic block or its scan input port connected to the output of another scan cell or an external scan input, depending on the value of its corresponding scan enable (SE) signal. When a scan enable (SE) signal is enabled, usually with logic value 1, any scan cell under its control accepts its input value from its scan input port. Generally, scan enable signals SE1 155 to SE4 158, together with test enable signals TE1 151 to TE4 154, are also used to repair various DFT (design-for-test) design rule violations, including asynchronous set/reset violations. In addition, test enable signals TE1 151 to TE4 154 can be driven by a test mode selection signal, say TE, during scan-test or self-test.

A scan-based integrated circuit, such as the one shown in FIG. 1B, can be tested in either scan-test mode or self-test mode, by repeating three operations: shift-in, capture, and shift-out, until a limiting criteria is reached. The three operations are described bellow:

During the shift-in operation, a stimulus is shifted through scan inputs 159 to 162 into all scan cells SC in all scan chains SCN within the four clock domains CD1 101 to CD4 104, simultaneously. The stimulus is either a predetermined stimulus supplied from an ATE (automatic test equipment) in scan-test mode or a pseudo-random stimulus automatically generated in the scan-based integrated circuit using a pseudo-random pattern generator (PRPG) in self-test mode. After the shift-in operation is completed, capture clocks CK1 112 to CK4 115 are applied to all clock domains, CD1 101 to CD4 104, to capture the test response into scan cells SC. After the capture operation is completed, the test responses held by all scan cells are shifted out through scan outputs 163 to 166 during the shift-out operation while the next stimulus is shifted into all scan cells SC at the same time. The shifted-out test response is either compared directly with the expected response on an ATE in scan-test mode or compacted by a compactor, such as a multiple-input signature register (MISR), in self-test mode.

In any scan-based DFT (design-for-test) technique, the asynchronous set/reset ports of all scan cells must be disabled during the shift operation, including shift-in and shift-out; otherwise, the data that are being shifted into scan chains may be destroyed. If an asynchronous set/reset signal is not controlled directly by a primary input during scan-test or a BIST (built-in self-test) controller during self-test, it will be difficult or even impossible to disable the asynchronous set/reset signal during the shift operation. This is a scan-based DFT design rule violation that must be repaired.

Generally, there are four types of asynchronous set/reset violations: sequentially-gated set/reset violations, combinationally-gated set/reset violations, generated set/reset violations, and destructive set/reset violations. In a sequentially-gated set/reset violation, the set/reset signal of a scan cell can be traced back to a specified set/reset source gated with the output of a memory element such as a flip-flop or a latch. In a combinationally-gated set/reset violation, the set/reset signal of a scan cell can be traced back to a specified set/reset source gated with a primary input or the output of a combinational logic block. In a generated set/reset violation, the set/reset signal of a scan cell cannot be traced back to any primary input specified as a set/reset source. In a destructive set/reset violation of a scan cell, the set/reset signal is stuck at a certain logic value that sets or resets the scan cell constantly.

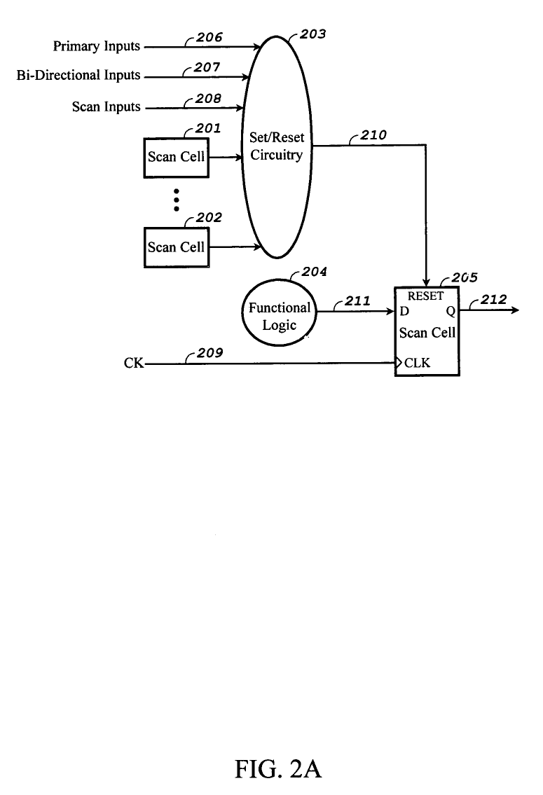

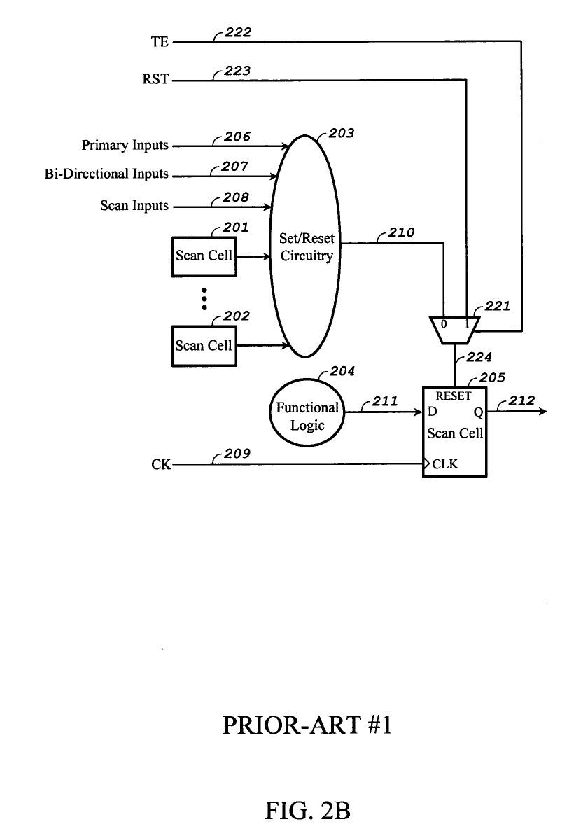

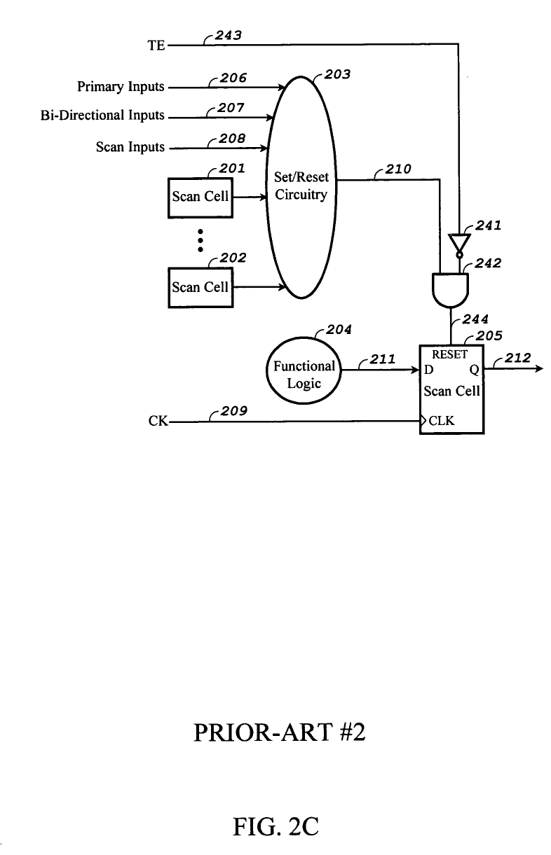

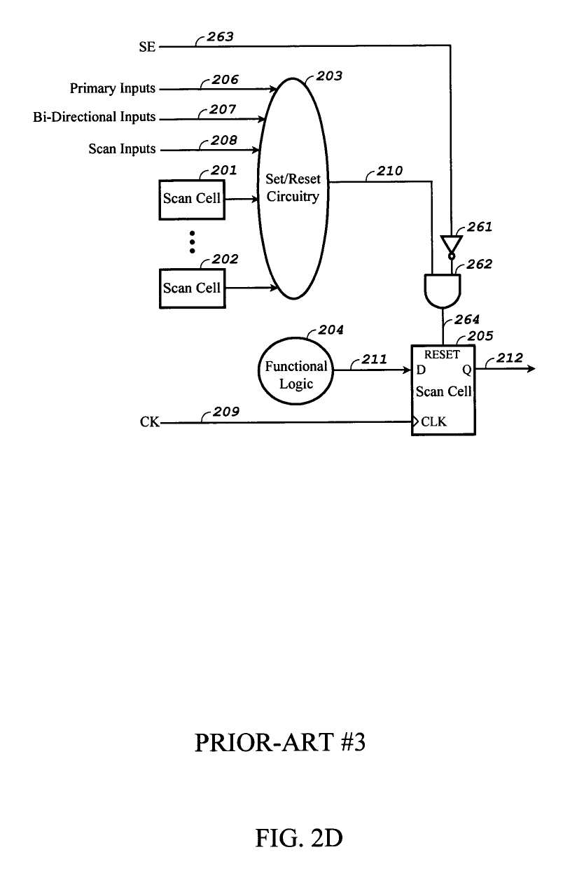

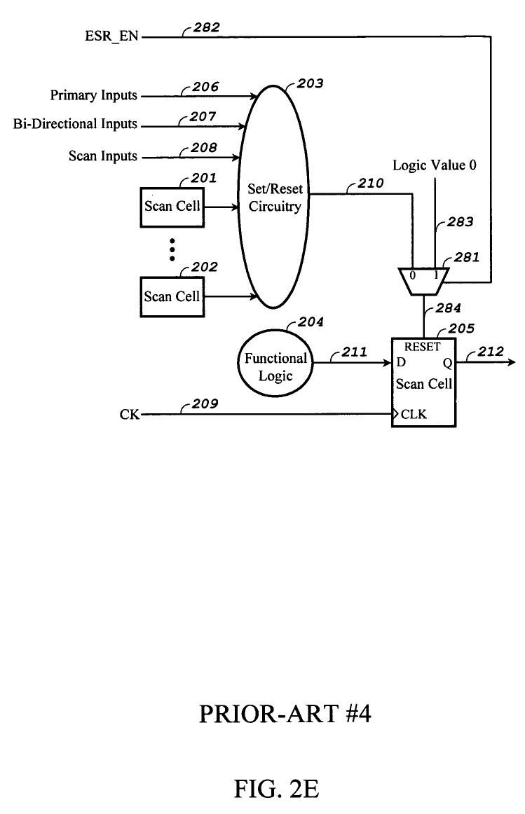

FIG. 2A shows an example design 200 with an asynchronous reset violation. The asynchronous reset signal 210 of the scan cell 205 violates the asynchronous set/reset DFT design rule since it is not controlled directly by a primary input. The asynchronous reset signal 210 is generated by a set/reset circuitry 203, driven by primary inputs 206, bi-directional primary inputs 207, external scan inputs 208, and the outputs of scan cells 201, 202, etc. During the shift operation, one must disable the asynchronous reset signal 210 by forcing logic value 0 on the signal. This puts strong constraints on the values that can be shifted into scan cells 201, 202, etc., as well as the values that primary inputs 206, bi-directional primary inputs 207, and scan inputs 208 can hold during the shift operation. In scan-test based ATPG (automatic test pattern generation), these constraints can result in long test patterns (comprising stimuli and test responses) and low fault coverage. In a self-test based environment, not satisfying these constraints will cause mismatches during compaction, thus invalidating the test.

FIG. 2B shows the result 220 of applying the prior-art #1 solution to repair the asynchronous reset violation shown in FIG. 2A. This solution uses a multiplexor 221 controlled by the test enable (TE) signal 222 to select either the original asynchronous set/reset signal 210 or an external reset signal RST 223 to provide a reset signal to the scan cell 205. During the entire test process, the external reset signal RST 223 is selected. As a result, the reset port of the scan cell 205 is disabled and the shift operation can be conducted correctly. In addition, the external reset signal RST 223 toggles during the capture operation. As a result, all faults propagating from the external reset signal RST 223 to the reset port of the scan cell 205 through the multiplexor 221 could be detected. However, asynchronous set/reset faults present in the set/reset circuitry 203 can never be detected. This may result in significant fault coverage loss when there are many asynchronous set/reset faults in the asynchronous set/reset circuitry 203.

FIG. 2C shows the result 240 of applying the prior-art #2 solution to repair the asynchronous reset violation shown in FIG. 2A. One inverter 241 and one AND gate 242 are used instead of the multiplexor 221 used in FIG. 2B. This prior-art solution does not need any external set/reset signal, such as RST 223 shown in FIG. 2B. This solution has lower overhead but yields more fault coverage loss than prior-art #1, as it cannot detect any faults present at the set/reset ports of scan cells.

FIG. 2D shows the result 260 of applying the prior-art #3 solution to repair the asynchronous reset violation shown in FIG. 2A. This solution uses a scan enable (SE) signal 263 together with an AND gate 262 and an inverter 261 to disable the asynchronous reset port of the scan cell 205. This solution ensures that the asynchronous reset port of the scan cell 205 is disabled during the shift operation. In addition, the asynchronous set/reset faults in the set/reset circuitry 203 can be propagated to the scan cell 205 during the capture operation. Thus, unlike the prior-art #1 and prior-art #2 solutions, there will be no fault coverage loss theoretically. The problem with this solution is that any value change at the data port and asynchronous reset port of the scan cell 205 can occur and be captured simultaneously, when the clock CK 209 is applied. As a result, race conditions and glitches may occur on the Q output 212 of the scan cell 205 during the capture operation. This will cause pattern mismatches during comparison or compaction, thus invalidating the test.

FIG. 2E shows the result 280 of applying the prior-art #4 solution to repair the asynchronous reset violation shown in FIG. 2A. This solution uses a multiplexor 281 controlled by the external set/reset enable (ESR_EN) signal 282 to disable the asynchronous reset port of the scan cell 205 during scan-test. During the shift operation, the ESR_EN signal 282 is set to logic value 1 so that any data being shifted into the scan cell 205 will not be destroyed. During the capture operation, two options are possible. In one option, the ESR_EN signal 282 is set to logic value 0 to allow faults in the set/reset circuitry 203 to be detected. In the other option, the ESR_EN signal 282 is set to logic value 1 to disable the asynchronous reset port of the scan cell 205 while the clock CK 209 is applied to test faults propagated to the data port 211 of the scan cell 205. In addition, being able to disable the asynchronous reset port of the scan cell 205 also helps to prevent any glitch at the output 210 of the set/reset circuitry 203 from affecting the state of the scan cell 205.

The advantage of this solution is that the faults in the set/reset circuitry 203 can now be propagated and tested during the capture operation and no glitches will be caused due to race conditions between the clock CK 209 and the asynchronous reset port of the scan cell 205. In addition, by properly controlling multiple ESR_EN signals, one can avoid any glitches due to a ripple set/reset condition where setting or resetting a set of scan cells creates an intermediate state forcing another set of scan cells to be set or reset unexpectedly.

However, this solution suffers from two problems: First, the ESR_EN signal needs to be an external pin, making it infeasible for a design with a tight pin count budget. Second, the ESR_EN signal is not qualified with a scan enable (SE) signal; as a result, it is impossible to use this solution in a self-test environment without destroying the contents of the scan chains during the shift operation.

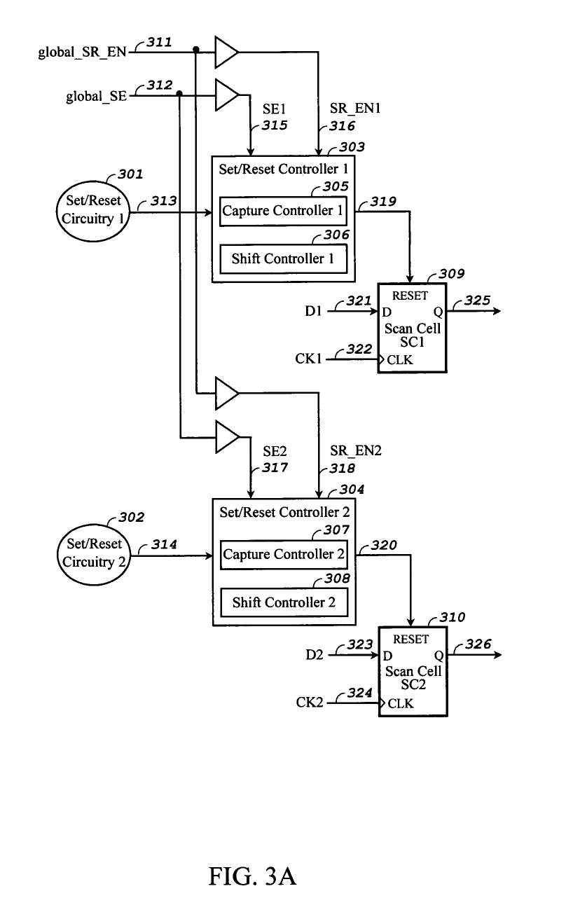

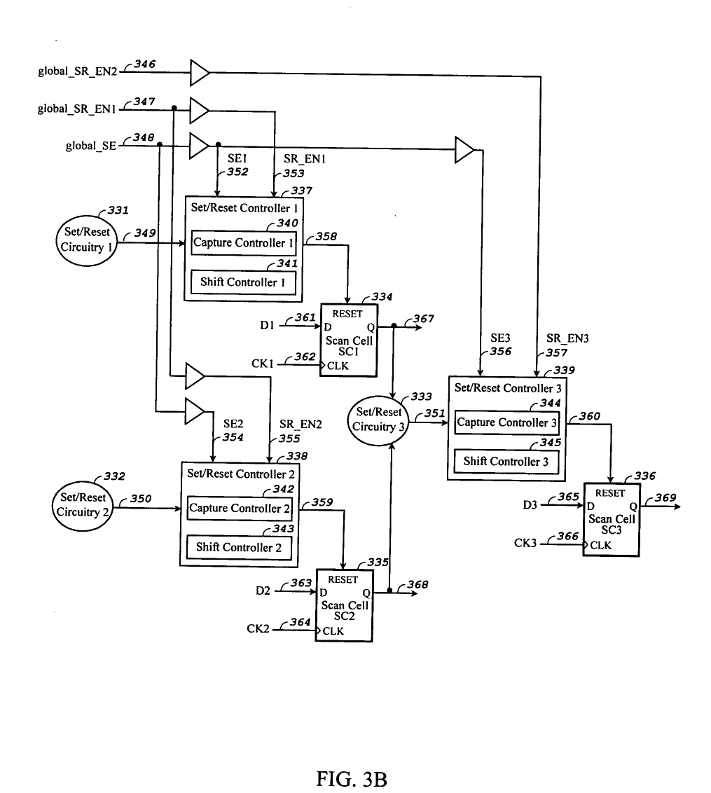

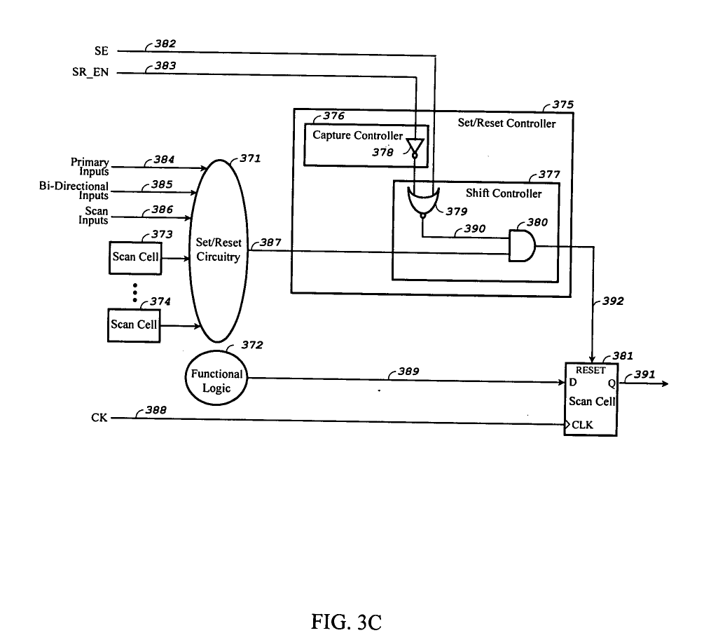

FIG. 3A shows a block diagram 300 of two set/reset controllers in a design without any ripple structure, in accordance with the present invention. The set/reset controller 303, controlled by a local scan enable signal SE1 315 and a local set/reset enable signal SR_EN1 316, consists of a capture controller 305 and a shift controller 306. The set/reset controller 304, controlled by a local scan enable signal SE2 317 and a local set/reset enable signal SR_EN2 318, consists of a capture controller 307 and a shift controller 308. The local scan enable signals SE1 315 and SE2 317 are driven by a global scan enable signal global_SE 312. The local set/reset enable signals SR_EN1 316 and SR_EN2 318 are driven by a global set/reset enable signal global_SR_EN 311. Note that the global scan enable signal global_SE 312 and the global set/reset enable signal global_SR_EN 311 are either generated in the scan-based integrated circuit under test or provided as an input signal to the scan-based integrated circuit. In addition, it is assumed that there is no path from the Q output 326 of the scan cell SC2 310 to the set/reset circuitry 301 and that there is no path from the Q output 325 of the scan cell SC1 309 to the set/reset circuitry 302. That is, there is no ripple structure existing between the two scan cells SC1 309 and SC2 310.

A set/reset controller can avoid race conditions and glitches that may arise in the prior-art #3 solution, while preserving its capability of detecting asynchronous set/reset faults in a scan-based integrated circuit. For example, the set/reset controller 303 consists of the capture controller 305 and the shift controller 306. The set/reset controller 303 provides a new asynchronous set/reset signal 319, controlled by two enable signals, namely the scan enable SE1 315 and the set/reset enable SR_EN1 316. The shift controller 306 is used to guarantee that the new asynchronous set/reset signal 319 remains disabled during the shift operation in order to avoid destroying any data that are being shifted into the scan cell 309. The capture controller 305, together with the shift controller 306, is used to realize a two-stage control on the new asynchronous set/reset signal 319 during the capture operation to guarantee that faults present in the original asynchronous set/reset circuitry 301 are detected without any race condition or glitch.

At the first stage of the capture operation, the SR_EN1 signal 316 is set to logic value 0, and capture clocks are applied to capture the test response into all scan cells through their data ports. At this stage, the new asynchronous set/reset signal 319 is disabled, ensuring that no race conditions and glitches arise. At the second stage of the capture operation, the SR_EN1 signal 316 is set to logic value 1 while disabling all capture clocks to allow the faults present in the original asynchronous set/reset circuitry 301 to be propagated via 319 to the scan cell 309. As a result, the faults present in the original asynchronous set/reset circuitry 301 can be detected.

FIG. 3B shows a block diagram 330 of three set/reset controllers in a design with a two-stage ripple structure, in accordance with the present invention.

The set/reset controller 337, controlled by a local scan enable signal SE1 352 and a local set/reset enable signal SR_EN1 353, consists of a capture controller 340 and a shift controller 341. The set/reset controller 338, controlled by a local scan enable signal SE2 354 and a local set/reset enable signal SR_EN2 355, consists of a capture controller 342 and a shift controller 343. The set/reset controller 339, controlled by the scan enable signal SE3 356 and the set/reset enable signal SR_EN3 357, consists of a capture controller 344 and a shift controller 345.

In addition, it is assumed that there is no path from the Q output 368 of the scan cell SC2 335 to the set/reset circuitry 331 and that there is no path from the Q output 367 of the scan cell SC1 334 to the set/reset circuitry 332. That is, there is no ripple structure existing between the two scan cells SC1 334 and SC2 335. However, note that the set/reset circuitry 333 accepts inputs from scan cells SC1 334 and SC2 335. Obviously, this is a two-stage ripple structure. If both SC1 334 and SC2 335 change states simultaneously, possible race conditions may cause glitches to reset the scan cell SC3 336 unexpectedly during test.

To avoid such scenario, two global set/reset enable signals global_SR_EN1 347 and global_SR_EN2 346 are used. The global_SR_EN1 signal 347 is used to drive two local set/reset enable signals SR_EN1 353 and SR_EN2 355 for the scan cells SC1 334 and SC2 335 in the first stage of the ripple structure. The global_SR_EN2 signal 346 is used to drive one local set/reset enable signal SR_EN3 357 for the scan cell SC3 336 in the second stage of the ripple structure. In addition, one global scan enable signal global_SE 348 is used to drive all three local scan enable signals SE1 352, SE2 354, and SE3 356. Note that the global scan enable signal global_SE 348, the global set/reset enable signals global_SR_EN1 347 and global_SR_EN2 346 are either generated in the scan-based integrated circuit under test or provided as an input signal to the scan-based integrated circuit.

During the shift operation, the global_SE signal 348 is set to logic value 1. This will disable the asynchronous set/reset signals 358 to 360 so that the data that are being shifted into the scan cells SC1 334 to SC3 336 will not be destroyed. During the capture operation, clocks CK1 362, CK2 364, and CK3 366 are applied first to test data faults propagated via D1 361, D2 363, and D3 365. During data fault testing, global set/reset enable signals global_SR_EN1 347 and global_SR_EN2 346 are set to disable the asynchronous set/reset signals 358 to 360 for the scan cells SC1 334 to SC3 336 to make sure that the testing of data faults will not be disturbed by the unexpected resetting of any scan cell. After data faults are tested by applying the clocks CK1 362, CK2 364, and CK3 366, the global set/reset enable signals global_SR_EN1 347 and global_SR_EN2 346 are set to allow faults in the set/reset circuitries 331 to 333 to be propagated to the scan cells s SC1 334 to SC3 336, respectively. Note that the global set/reset enable signals global_SR_EN1 347 and global_SR_EN2 346 are set in a way that they are not active simultaneously. This is to prevent the state changes of the scan cells SC1 334 and SC2 335 from causing any glitch for the scan cell SC3 336. As a result, the faults present in the original asynchronous set/reset circuitries 331 to 333 can be detected without any race conditions even in the presence of a ripple structure.

FIG. 3C shows an embodiment 370 of a set/reset controller, in accordance with the present invention. The capture controller 376 consists of one inverter 378. The shift controller 377 consists of one NOR gate 379 and one AND gate 380. During the shift operation, the scan enable signal SE 382 is set to logic value 1. As a result, the shift controller 375 will set the asynchronous reset signal 392 of the scan cell 381 to logic value 0. That is, the reset capability of the scan cell 381 will be disabled, preventing the data shifted to this scan cell from being destroyed. After the shift operation is completed, the circuit enters the capture operation when the scan enable signal SE 382 is set to logic value 0. At the first stage of the capture operation, the SR_EN signal 383 is set to logic value 0. As a result, the asynchronous reset signal 392 will remain disabled. The capture clock CK 388 is applied to capture the faults present in the functional logic block 372 into the scan cell 381 via its data input port 389. At the second stage of the capture operation, the capture clock CK 388 is disabled and the SR_EN signal 383 is set to logic value 1. This will set the signal 390 to logic value 1 enabling the propagation of the faults present in the original set/reset circuitry 371 to the scan cell 381 via its asynchronous reset port RESET 392.

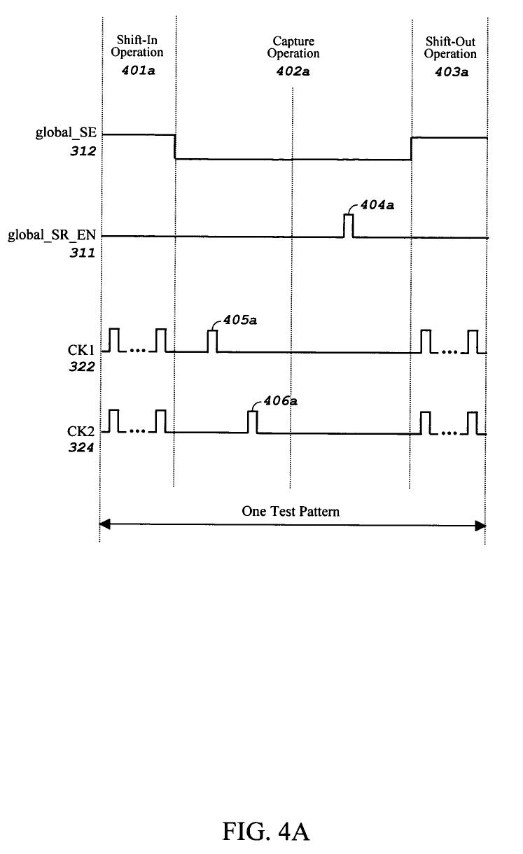

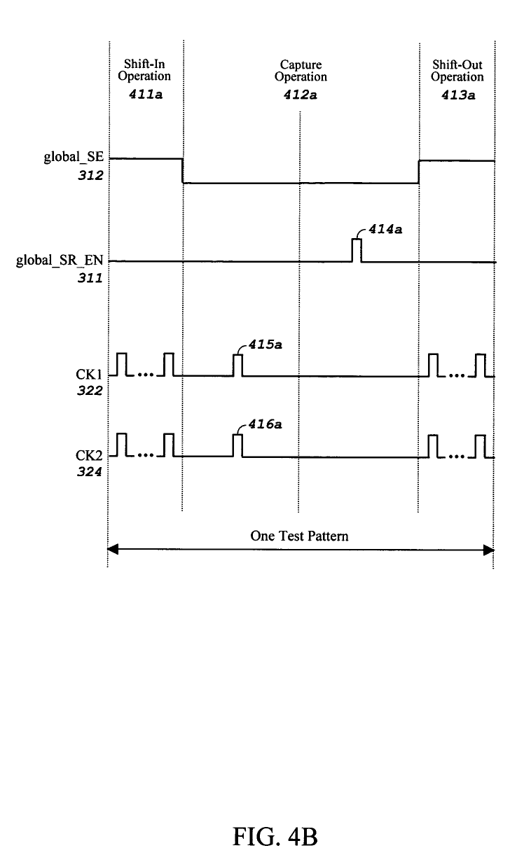

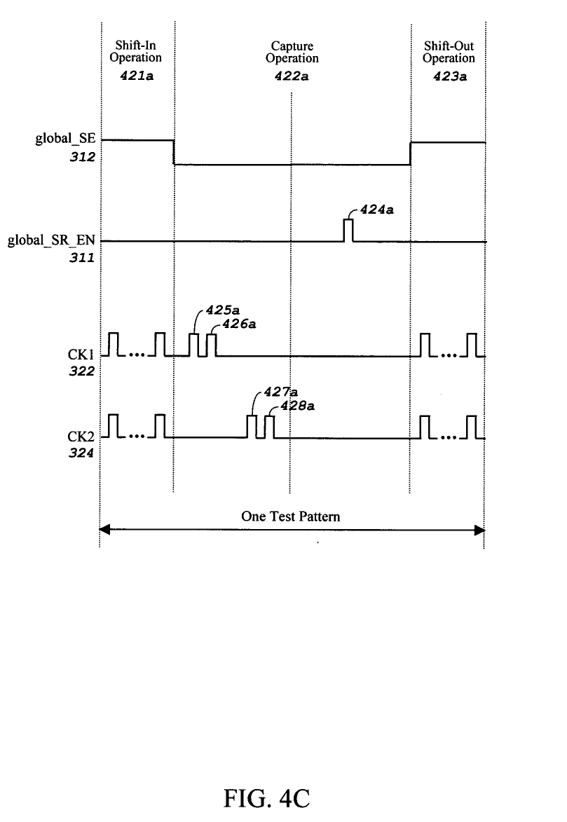

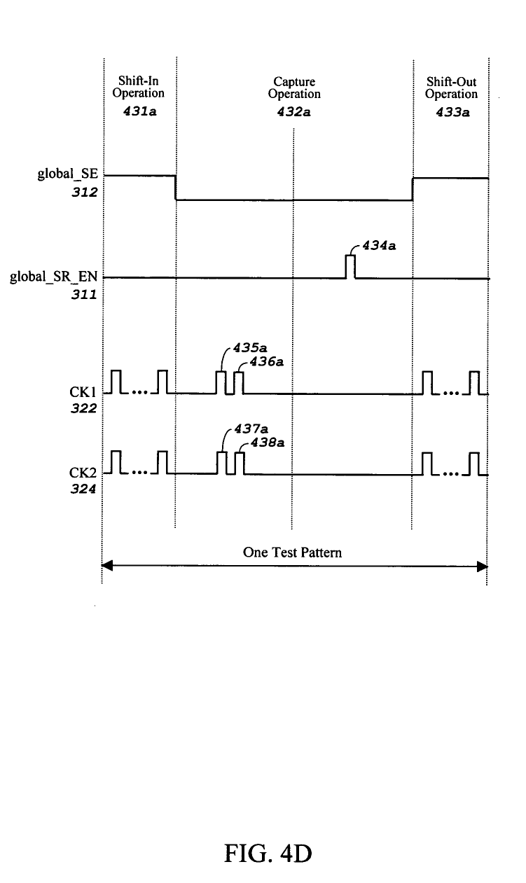

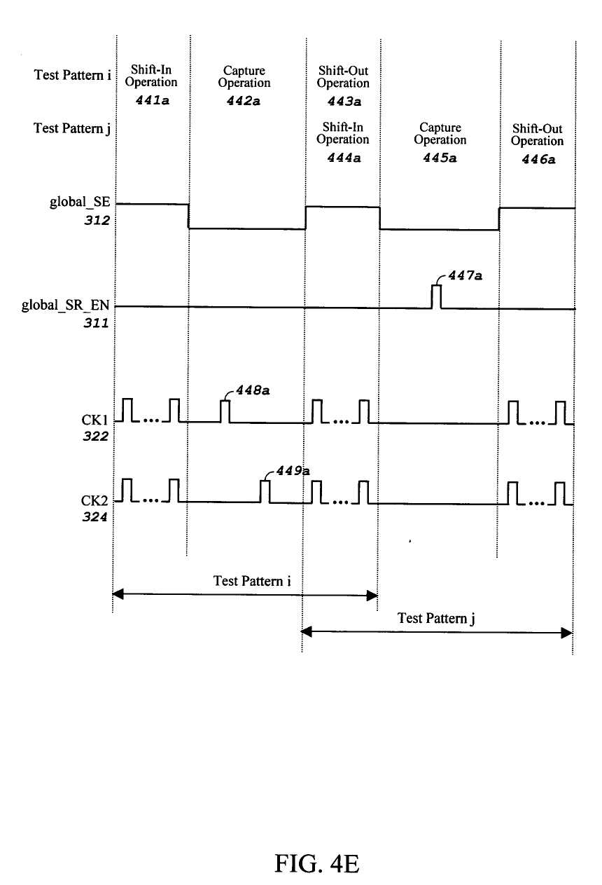

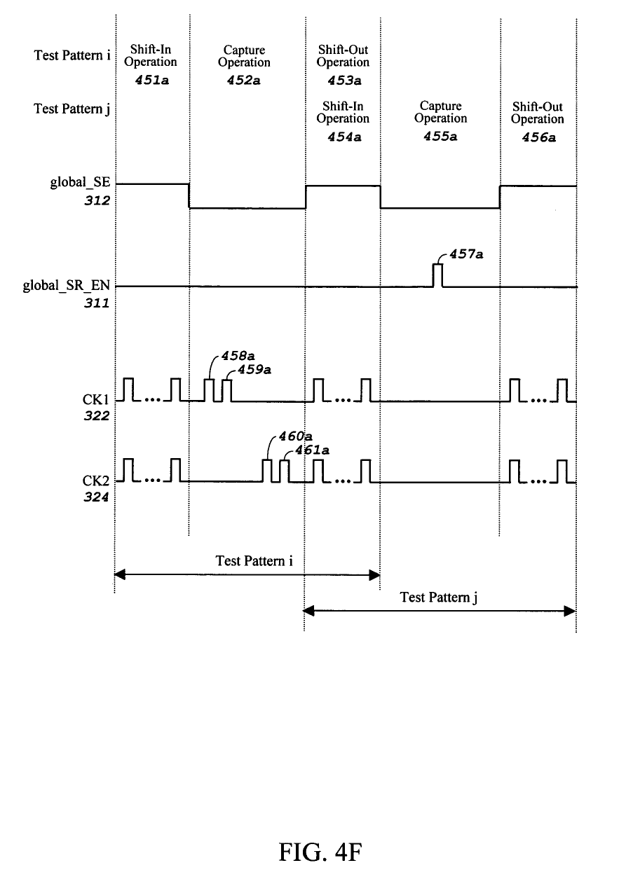

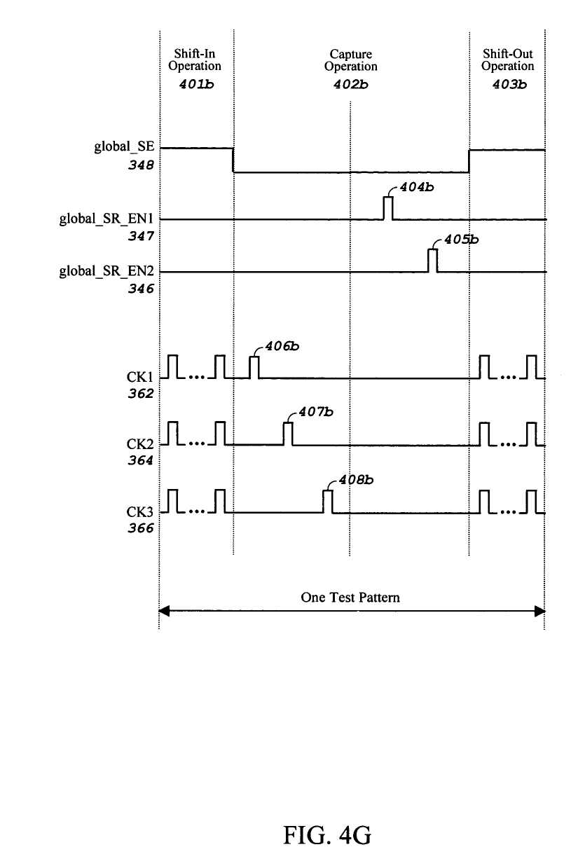

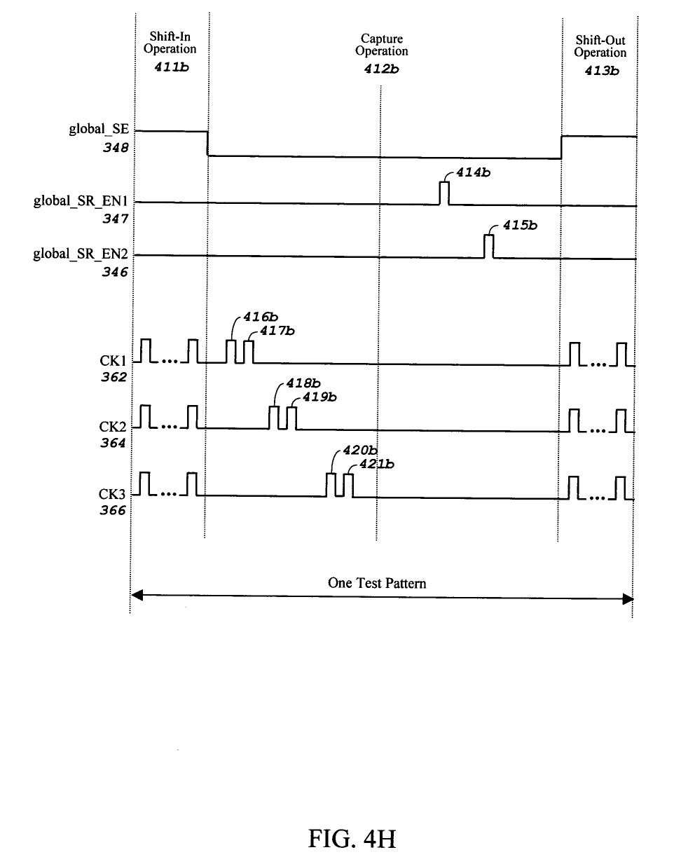

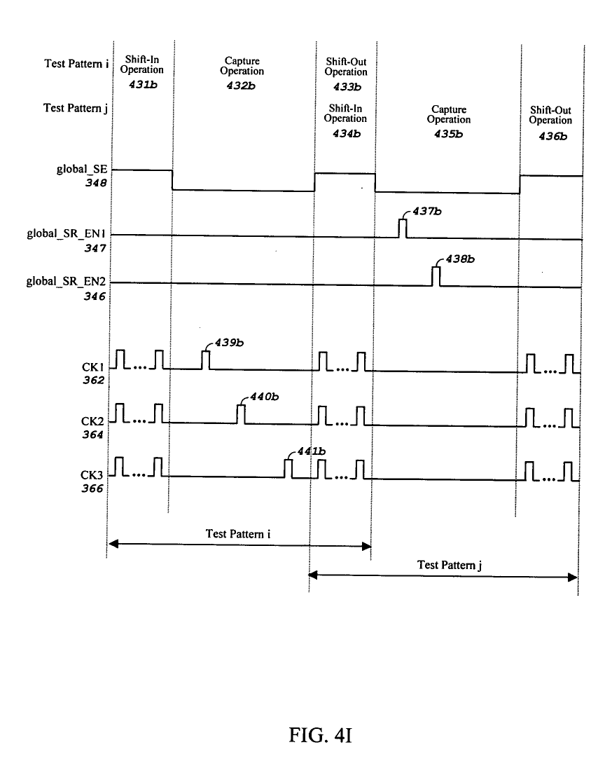

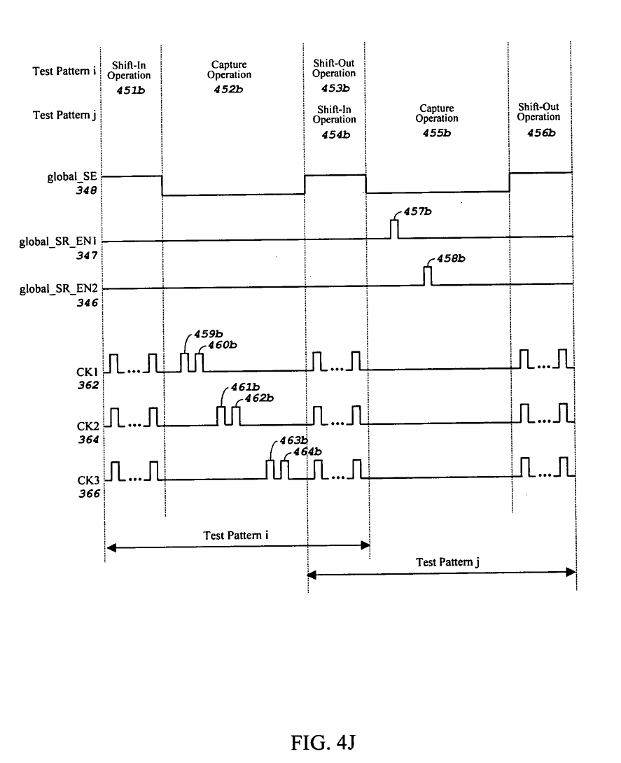

FIG. 4A shows a timing diagram 400a for testing the design without any ripple structure shown in FIG. 3A, in accordance with the present invention, where both data faults and set/reset faults are detected during the same capture operation with non-overlapping single-capture clocks. During the first cycle in the capture operation 402a, two single pulses are applied to the capture clocks CK1 322 and CK2 324 in a non-overlapping manner as shown at 405a and 406a to detect data faults while the global set/reset enable global_SR_EN 311 is set to logic value 0. This non-overlapping capture clock scheme is used to avoid the impact of clock skews between two clock domains. Then, during the second cycle in the same capture operation 402a, the global set/reset enable global_SR_EN 311 is set to logic value 1 as shown at 404a while the capture clocks CK1 322 and CK2 324 are inactive; as a result, set/reset faults are detected.

FIG. 4B shows a timing diagram 410a for testing the design without any ripple structure shown in FIG. 3A, in accordance with the present invention, where both data faults and set/reset faults are detected during the same capture operation with overlapping single-capture clocks. During the first cycle in the capture operation 412a, two single pulses are applied to the capture clocks CK1 322 and CK2 324 in an overlapping manner as shown at 415a and 416a to detect data faults while the global set/reset enable global_SR_EN 311 is set to logic value 0. This overlapping capture clock scheme can be used when there is no interaction between two clock domains or clock skews between two clock domains are properly managed. Then, during the second cycle in the same capture operation 412a, the global set/reset enable global_SR_EN 311 is set to logic value 1 as shown at 414a while the capture clocks CK1 322 and CK2 324 are inactive; as a result, set/reset faults are detected.

FIG. 4C shows a timing diagram 420a for testing the design without any ripple structure shown in FIG. 3A, in accordance with the present invention, where both data faults and set/reset faults are detected during the same capture operation with non-overlapping at-speed double-capture clocks. During the first cycle in the capture operation 422a, two at-speed double pulses are applied to the capture clocks CK1 322 and CK2 324 in a non-overlapping manner as shown at 425a to 428a to detect data faults while the global set/reset enable global_SR_EN 311 is set to logic value 0. This non-overlapping capture clock scheme is used to avoid the impact of clock skews between two clock domains. Then, during the second cycle in the same capture operation 422a, the global set/reset enable global_SR_EN 311 is set to logic value 1 as shown at 424a while the capture clocks CK1 322 and CK2 324 are inactive; as a result, set/reset faults are detected. This timing diagram shows that delay faults in functional logic can be tested with a double-capture approach, in accordance with the present invention. Note that delay faults can also be tested with a single-capture or last-shift-launch approach, in accordance with the present invention.

FIG. 4D shows a timing diagram 430a for testing the design without any ripple structure shown in FIG. 3A, in accordance with the present invention, where both data faults and set/reset faults are detected during the same capture operation with overlapping at-speed double-capture clocks. During the first cycle in the capture operation 432a, two at-speed double pulses are applied to the capture clocks CK1 322 and CK2 324 in an overlapping manner as shown at 435a to 438a to detect data faults while the global set/reset enable global_SR_EN 311 is set to logic value 0. This overlapping capture clock scheme can be used when there is no interaction between two clock domains or clock skews between two clock domains are properly managed. Then, during the second cycle in the same capture operation 432a, the global set/reset enable global_SR_EN 311 is set to logic value 1 as shown at 434a while the capture clocks CK1 322 and CK2 324 are inactive; as a result, set/reset faults are detected. This timing diagram shows that delay faults in functional logic can be tested with a double-capture approach, in accordance with the present invention. Note that delay faults can also be tested with a single-capture or last-shift-launch approach, in accordance with the present invention.

FIG. 4E shows a timing diagram 440a for testing the design without any ripple structure shown in FIG. 3A, in accordance with the present invention, where data faults and set/reset faults are detected during two capture operations with non-overlapping single-capture clocks. During the first capture operation 442a for test pattern i, two single pulses are applied to the capture clocks CK1 322 and CK2 324 as shown at 448a and 449a while the global set/reset enable global_SR_EN 311 is set to logic value 0 for the whole capture operation, in order for test pattern i to detect data faults. This non-overlapping capture clock scheme is used to avoid the impact of clock skews between two clock domains. Then, during the second capture operation 445a for test pattern j, the global set/reset enable global_SR_EN 311 is set to logic value 1 as shown at 447a while the capture clocks CK1 322 and CK2 324 are kept inactive for the whole capture operation, in order for test pattern j to detect set/reset faults.

FIG. 4F shows a timing diagram 450a for testing the design without any ripple structure shown in FIG. 3A, in accordance with the present invention, where data faults and set/reset faults are detected during two capture operations with non-overlapping at-speed double-capture clocks. During the first capture operation 452a for test pattern i, two at-speed double pulses are applied to the capture clocks CK1 322 and CK2 324 as shown at 458a to 461a while the global set/reset enable global_SR_EN 311 is set to logic value 0 for the whole capture operation, in order for test pattern i to detect data faults. This non-overlapping capture clock scheme is used to avoid the impact of clock skews between two clock domains. Then, during the second capture operation 455a for test pattern j, the global set/reset enable global_SR_EN 311 is set to logic value 1 as shown at 457a while the capture clocks CK1 322 and CK2 324 are kept inactive for the whole capture operation, in order for test pattern j to detect set/reset faults. This timing diagram shows that delay faults in functional logic can be tested with a double-capture approach, in accordance with the present invention. Note that delay faults can also be tested with a single-capture or last-shift-launch approach, in accordance with the present invention.

FIG. 4G shows a timing diagram 400b for testing the design with a two-stage ripple structure shown in FIG. 3B, in accordance with the present invention, where both data faults and set/reset faults are detected during the same capture operation with non-overlapping single-capture clocks. During the first cycle in the capture operation 402b, three single pulses are applied to the capture clocks CK1 362, CK2 364, and CK3 366 in a non-overlapping manner as shown at 406b to 408b to detect data faults while the global set/reset enable signals global_SR_EN1 347 and global_SR_EN2 346 are set to logic value 0. This non-overlapping capture clock scheme is used to avoid the impact of clock skews between two clock domains. Then, during the second cycle in the same capture operation, the global set/reset enable signals global_SR_EN1 347 and global_SR_EN2 346 are set to logic value 1 in a non-overlapping manner as shown at 404b and 405b while the capture clocks CK1 362, CK2 364, and CK3 366 are inactive; as a result, set/reset faults are detected. Note that the global set/reset enable signals global_SR_EN1 347 and global_SR_EN2 346 are not active at the same time. As a result, any glitch caused by state changes due to the active global set/reset enable signal global_SR_EN1 347 will not affect all scan cells controlled by the global set/reset enable signal global_SR_EN2 346.

FIG. 4H shows a timing diagram 410b for testing the design with a two-stage ripple structure shown in FIG. 3B, in accordance with the present invention, where both data faults and set/reset faults are detected during the same capture operation with non-overlapping at-speed double-capture clocks. During the first cycle in the capture operation 412b, three at-speed double pulses are applied to the capture clocks CK1 362, CK2 364, and CK3 366 in a non-overlapping manner as shown at 416b to 421b to detect data faults while the global set/reset enable signals global_SR_EN1 347 and global_SR_EN2 346 are set to logic value 0. This non-overlapping capture clock scheme is used to avoid the impact of clock skews between two clock domains. Then, during the second cycle in the same capture operation, the global set/reset enable signals global_SR_EN1 347 and global_SR_EN2 346 are set to logic value 1 in a non-overlapping manner as shown at 414b and 415b while the capture clocks CK1 362, CK2 364, and CK3 366 are inactive; as a result, set/reset faults are detected. Note that the global set/reset enable signals global_SR_EN1 347 and global_SR_EN2 346 are not active at the same time. As a result, any glitch caused by state changes due to the active global set/reset enable signal global_SR_EN1 347 will not affect all scan cells controlled by the global set/reset enable signal global_SR_EN2 346. This timing diagram shows that delay faults in functional logic can be tested with a double-capture approach, in accordance with the present invention. Note that delay faults can also be tested with a single-capture or last-shift-launch approach, in accordance with the present invention.

FIG. 41 shows a timing diagram 430b for testing the design with a two-stage ripple structure shown in FIG. 3B, in accordance with the present invention, where data faults and set/reset faults are detected during two capture operations with non-overlapping single-capture clocks. During the first capture operation 432b for test pattern i, three single pulses are applied to the capture clocks CK1 362, CK2 364, and CK3 366 as shown at 439b to 441b while the global set/reset enable signals global_SR_EN1 347 and global_SR_EN2 346 are set to logic value 0 for the whole capture operation, in order for test pattern i to detect data faults. This non-overlapping capture clock scheme is used to avoid the impact of clock skews between two clock domains. Then, during the second capture operation 435b for test pattern j, the global set/reset enable signals global_SR_EN1 347 and global_SR_EN2 346 are set to logic value 1 as shown at 437b and 438b in a non-overlapping manner while the capture clocks CK1 362, CK2 364, and CK3 366 are kept inactive for the whole capture operation, in order for test pattern j to detect set/reset faults. Note that the global set/reset enable signals global_SR_EN1 347 and global_SR_EN2 346 are not active at the same time. As a result, any glitch caused by state changes due to the active global set/reset enable signal global_SR_EN1 347 will not affect all scan cells controlled by the global set/reset enable signal global_SR_EN2 346.

FIG. 4J shows a timing diagram 450b for testing the design with a two-stage ripple structure shown in FIG. 3B, in accordance with the present invention, where data faults and set/reset faults are detected during two capture operations with non-overlapping at-speed double-capture clocks. During the first capture operation 452b for test pattern i, three at-speed double pulses are applied to the capture clocks CK1 362, CK2 364, and CK3 366 as shown at 459b to 464b while the global set/reset enable signals global_SR_EN1 347 and global_SR_EN2 346 are set to logic value 0 for the whole capture operation, in order for test pattern i to detect data faults. This non-overlapping capture clock scheme is used to avoid the impact of clock skews between two clock domains. Then, during the second capture operation 455b for test pattern j, the global set/reset enable signals global_SR_EN1 347 and global_SR_EN2 346 are set to logic value 1 as shown at 457b and 458b while the capture clocks CK1 362, CK2 364, and CK3 366 are kept inactive for the whole capture operation, in order for test pattern j to detect set/reset faults. Note that the global set/reset enable signals global_SR_EN1 347 and global_SR_EN2 346 are not active at the same time. As a result, any glitch caused by state changes due to the active global set/reset enable signal global_SR_EN1 347 will not affect all scan cells controlled by the global set/reset enable signal global_SR_EN2 346. This timing diagram shows that delay faults in functional logic can be tested with a double-capture approach, in accordance with the present invention. Note that delay faults can also be tested with a single-capture or last-shift-launch approach, in accordance with the present invention.

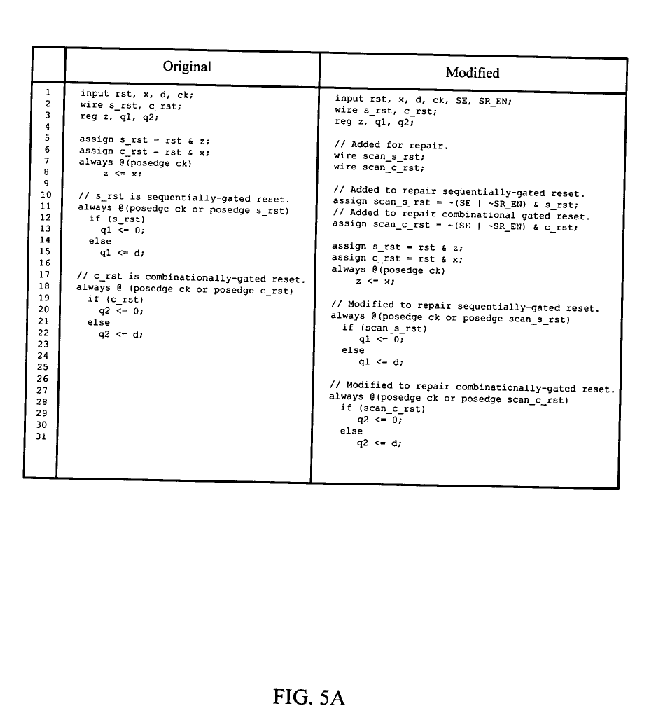

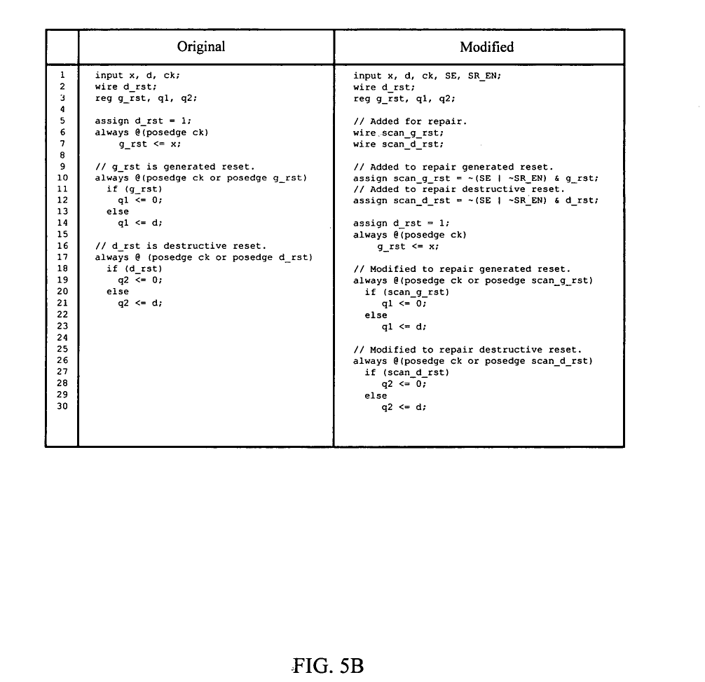

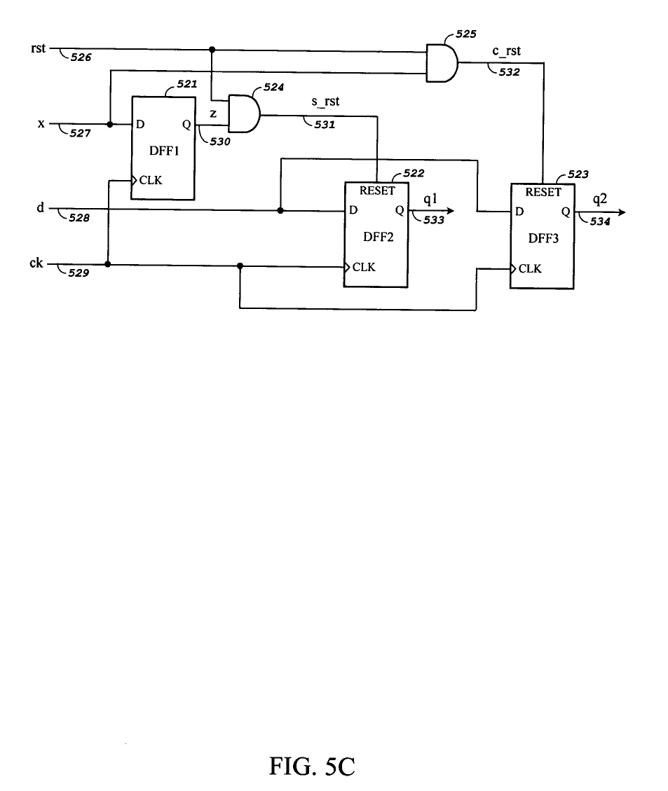

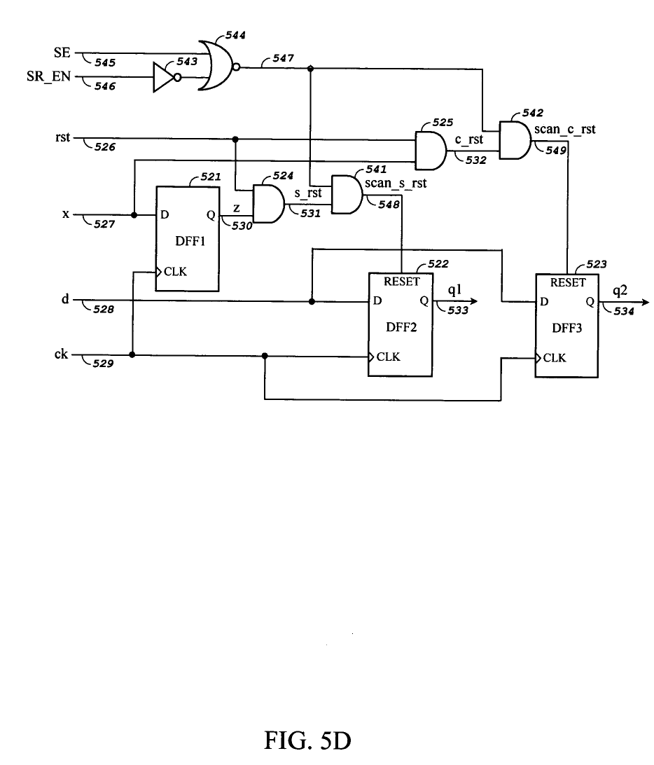

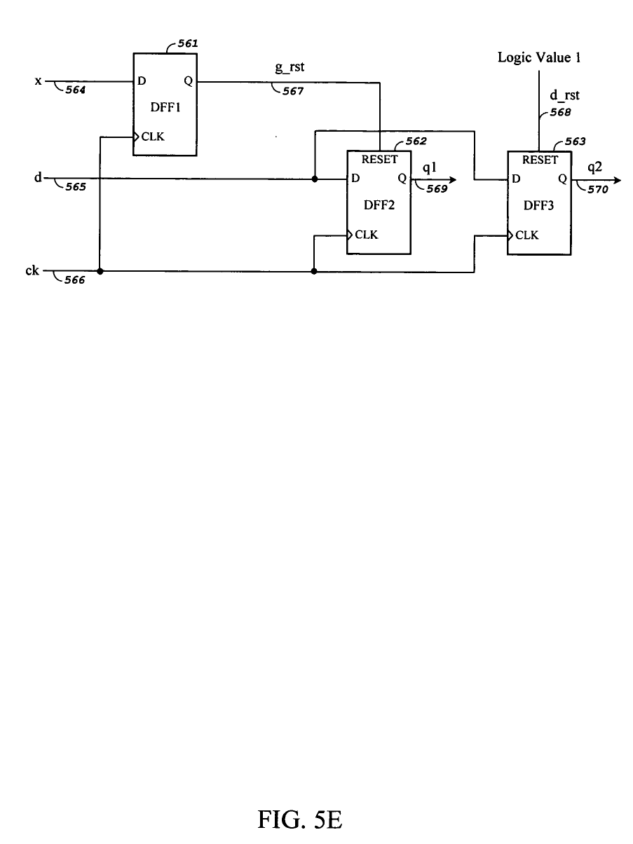

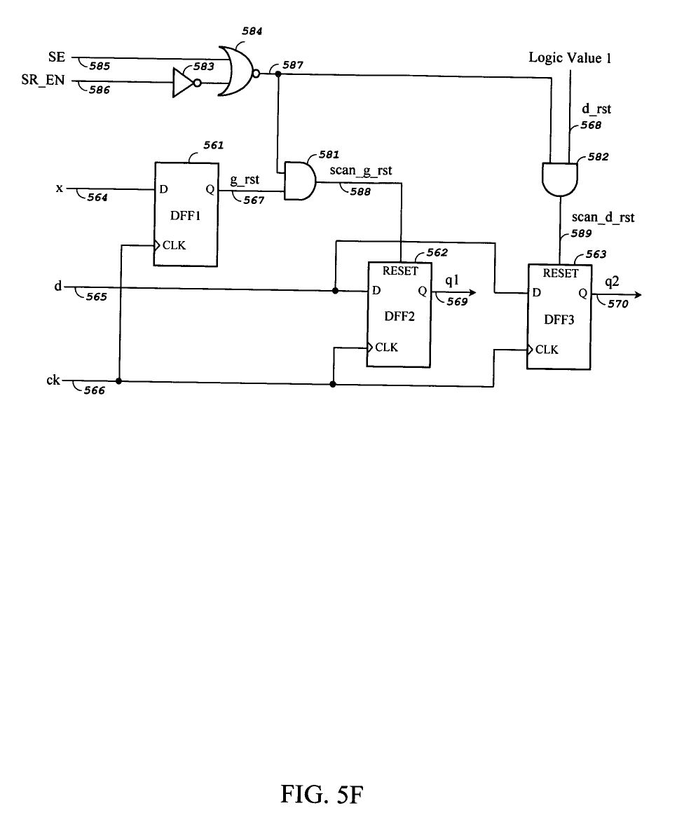

FIG. 5A shows an example set 500 of RTL (register-transfer level) Verilog codes before and after a sequentially-gated reset violation and a combinationally-gated reset violation are repaired, in accordance with the present invention.

In the original RTL Verilog code, the asynchronous reset signal s_rst on line 11, of the D flip-flop inferred for signal q1 in the always block starting from line 11, can be traced back to the output of the D flip-flop inferred for signal z in the always block starting from line 7. Note that z is gated with the specified reset source signal rst on line 5 and the result is the asynchronous reset signal s_rst on line 5. As a result, this is a sequentially-gated reset violation. On the other hand, the asynchronous reset signal c_rst on line 18, of the D flip-flop inferred for signal q2 in the always block starting from line 18, can be traced back to the primary input x on line 6. Note that x is gated with the specified reset source rst on line 6 and the result is the asynchronous reset signal c_rst on line 6. As a result, this is a combinationally-gated reset violation.

In the modified RTL Verilog code, two new signals, scan_s_rst on line 6 and scan_c_rst on line 7, are added to model the repaired s_rst and c_rst signals, respectively. The continuous assignment statements on lines 10 and 12 describe the set/reset controllers that are inserted to repair the sequentially-gated reset violation and the combinationally-gated reset violation, respectively. When SE is set to logic value 0 and SR_EN is set to logic value 1, the modified circuit behavior is the same as the original one. When SE has logic value 1, scan_s_rst and scan_c_rst will become logic value 0, thus disabling the asynchronous reset operation of the D flip-flops inferred for signals q1 and q2 in the always blocks starting from lines 20 and 27, respectively.

FIG. 5B shows an example set of RTL (register-transfer level) Verilog codes 510 before and after a generated reset violation and a destructive reset violation are repaired, in accordance with the present invention.

In the original RTL Verilog code, the asynchronous reset signal g_rst on line 10, of the D flip-flop inferred for signal q1 in the always block starting from line 10, can be traced back to the output of the D-flip flop inferred for g_rst described in the always block starting from line 6. As a result, this is a generated reset violation. On the other hand, the asynchronous reset signal d_rst on line 17, of the D flip-flop inferred for signal q2 in the always block starting from line 17, is always stuck at logic value 1. As a result, this is a destructive reset violation because the D flip-flop inferred for signal q2 in the always block starting from line 17 will always be reset.

In the modified RTL Verilog code, two new signals, scan_g_rst on line 6 and scan_d_rst on line 7, are added to model the repaired g_rst and d_rst signals, respectively. The continuous assignment statements on lines 10 and 12 model the added set/reset controllers that repair the generated reset violation and the destructive reset violation, respectively. When SE has logic value 0 and SR_EN is set logic value 1, the RTL circuit behavior is the same as the original one; when SE has logic value 1, the signal scan_g_rst and scan_d_rst will become logic value 0, thus disabling the asynchronous reset operation of the D flip-flops inferred for signals q1 and q2 in the always block starting from lines 19 and 26, respectively.

FIG. SC shows the gate-level circuit model 520 corresponding to the original RTL (register-transfer level) code shown in FIG. 5A. D flip-flops DFF2 522 and DFF3 523 are reset by asynchronous signals s_rst 531 and c_rst 532, respectively. Since the value of s_rst 531 is determined by an AND gate 524 with the output z 530 of the D flip-flop DFF1 521 as one of its inputs, this is a sequentially-gated reset violation. Since the value of c_rst 532 is determined by an AND gate 525 with only primary inputs rst 526 and x 527 as its inputs, this is a combinationally-gated reset violation.

FIG. 5D shows the gate-level circuit model 540 obtained after the sequentially-gated reset violation and the combinationally-gated reset violation shown in FIG. 5C are repaired, in accordance with the present invention. The set/reset controllers that are added to disable the reset operations of D flip-flops DFF2 522 and DFF3 523 consist of two AND gates 541 and 542, one inverter 543, and one NOR gate 544.

In functional mode, SE 545 has logic value 0 and SR_EN 546 has logic value 1. As a result, the original reset signals s_rst 531 and c_rst 532 will be able to reset DFF2 522 and DFF3 523, respectively, as intended by the functionality of the circuit.

During the shift operation, SE 545 is set to logic value 1 while SR_EN 546 may take any logic value. As a result, the new reset signals scan_s_rst 548 and scan_c_rst 549 will become logic value 0, preventing DFF2 522 and DFF3 523 from being reset during the shift operation, respectively. Therefore, the shift operation can be conducted correctly.

During the capture operation, SE 545 is set to logic value 0. In the first stage of the capture operation, SR_EN 546 is set to logic value 0 and the capture clock ck 529 is applied to capture the faults from the signal line d 528 into DFF2 522 and DFF3 523. In the second stage of the capture operation, the capture clock ck 529 is disabled and SR_EN 546 is set to logic value 1. As a result, the logic value of signal 547 becomes logic value 1, which allows the faults from the original reset signals s_rst 531 and c_rst 532 to be propagated to DFF2 522 and DFF3 523, respectively. Therefore, fault coverage can be improved without any race condition or glitch.

FIG. SE shows the gate-level circuit model 560 corresponding to the original RTL (register-transfer level) code shown in FIG. 5B. D flip-flops DFF2 562 and DFF3 563 are reset by asynchronous signals g_rst 567 and d_rst 568, respectively. Since the reset signal g_jst 567 of DFF2 562 comes directly from the D flip-flop DFF1 561, this is a generated reset violation. Since the reset signal d_rst 568 of DFF3 563 is tied to VCC (logic value 1), this is a destructive reset violation.

FIG. 5F shows the gate-level circuit model 580 after the generated reset violation and the destructive reset violation shown in FIG. SE are repaired, in accordance with the present invention. The set/reset controllers that are added to disable the reset operations of D flip-flops DFF2 562 and DFF3 563 consist of two AND gates 581 and 582, one inverter 583, and one NOR gate 584.

In functional mode, SE 585 has logic value 0 and SR_EN 586 has logic value 1. As a result, the original reset signals g_rst 567 and d_rst 568 will be able to reset DFF2 562 and DFF3 563, respectively, as intended by the functionality of the circuit.

During the shift operation, SE 585 is set to logic value 1 while SR_EN 586 may take any logic value. As a result, the new reset signals scan_g_rst 588 and scan_d_rst 589 will become logic value 0, preventing DFF2 562 and DFF3 563 from being reset during the shift operation, respectively. Therefore, the shift operation can be conducted correctly.

During the capture operation, SE 585 is set to logic value 0. In the first stage of the capture operation, SR_EN 586 is set to logic value 0 and the capture clock ck 566 is applied to capture the faults from the signal line d 565 into DFF2 562 and DFF3 563. In the second stage of the capture operation, the capture clock ck 566 is disabled and SR_EN 586 is set to logic value 1. The logic value of the signal 587 becomes logic value 1, allowing the faults from the original reset signals g_rst 567 and d_rst 568 to be propagated to DFF2 562 and DFF3 563, respectively. Therefore, fault coverage can be improved without any race condition or glitch.

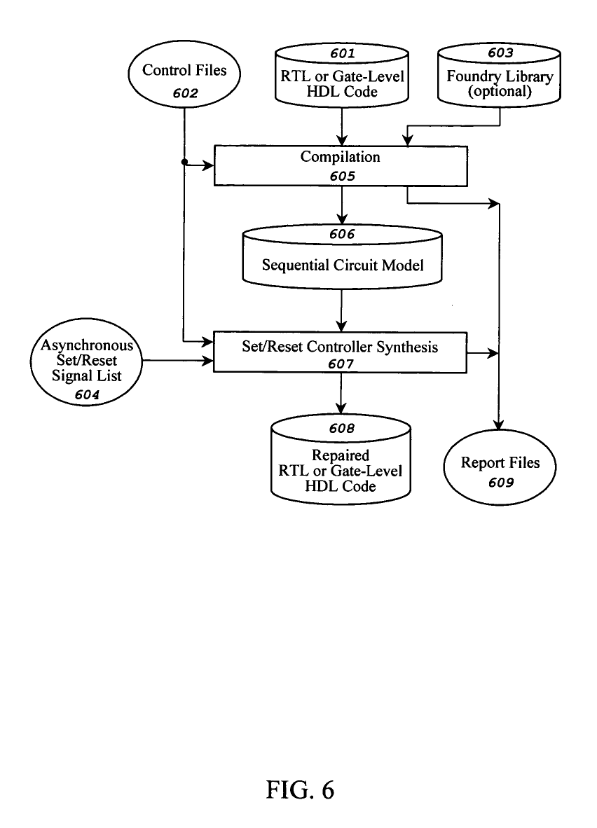

FIG. 6 shows a flow diagram 600 of the method for repairing asynchronous set/reset violations at either RTL (register-transfer level) or gate-level, in accordance with the present invention. The system 600, which consists of a number of computer-implemented steps, accepts the user-supplied synthesizable RTL or gate-level HDL (hardware design language) code 601 representing a scan-based integrated circuit design, the control files 602, a chosen foundry library 603, and an asynchronous set/reset signal list 604. The control files 602 contain all set-up information and scripts to control the steps of compiling 605 the HDL code 601 into a sequential circuit model 606 and automatic set/reset controller synthesis 607 at either RTL or gate-level. The automatic set/reset controller synthesis 607 produces repaired RTL or gate-level HDL code 608, which contains set/reset controllers added to repair all asynchronous set/reset signals specified by the list 604. All reports and errors are stored in the report files 609.

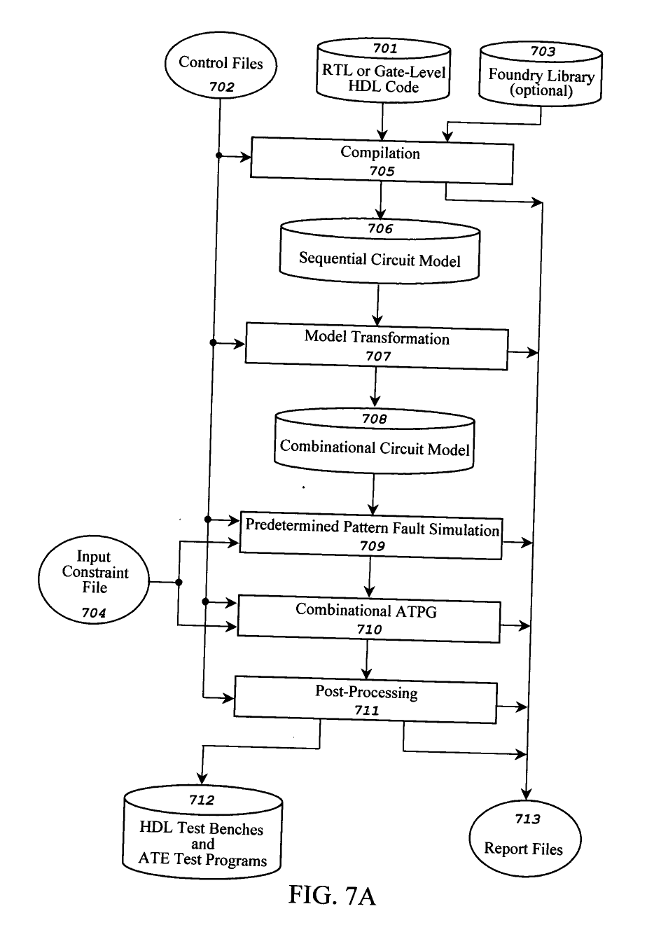

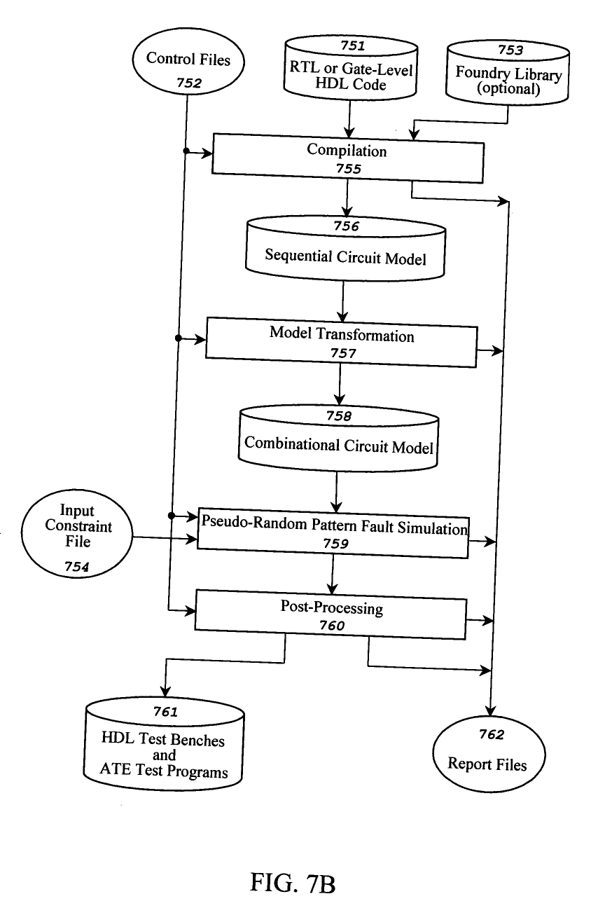

FIG. 7A shows a flow diagram 700 of the method for generating test patterns for data faults and set/reset faults in scan-test mode, in accordance with the present invention. The system 700 accepts the user-supplied RTL (register-transfer level) or gate-level HDL (hardware design language) code 701 representing a scan-based integrated circuit design whose asynchronous set/reset violations have been repaired. In addition, control files 702, a chosen foundry library 703, and an input constraint file 704 are also provided. The input constraint file 704 contains input constraints on all clocks, set/reset enable (SR_EN) signals, and scan enable (SE) signals. The control files 702 contain all set-up information and scripts required for compilation 705, model transformation 707, predetermined pattern fault simulation 709, combinational ATPG (automatic test pattern generation) 710, and post-processing 711. The compilation step 705 is to compile the HDL code 701 into a sequential circuit model 706. The model transformation step 707 is to convert the sequential circuit model 706 into an equivalent combinational circuit model 708. The predetermined pattern fault simulation step 709 is to identify the faults that are detected by a set of predetermined patterns. The combinational ATPG (automatic test pattern generation) step 710 is to generate test patterns for testing data faults and set/reset faults. Finally, the post-processing step 711 is to generate HDL test benches and ATE (automatic test equipment) test programs 712. All reports and errors are stored in the report files 713.

FIG. 7B shows a flow diagram 750 of the method for generating test patterns for data faults and set/reset faults in self-test mode, in accordance with the present invention. The system 750 accepts the user-supplied RTL (register-transfer level) or gate-level HDL (hardware design language) code 751 representing a scan-based integrated circuit design whose asynchronous set/reset violations have been repaired. In addition, control files 752, a chosen foundry library 753, and an input constraint file 754 are also provided. The input constraint file 754 contains input constraints on all clocks, set/reset enable (SR_EN) signals, and scan enable (SE) signals. The control files 752 contain all set-up information and scripts required for compilation 755, model transformation 757, pseudo-random pattern fault simulation 759, and post-processing 760. The compilation step 755 is to compile the HDL code 701 into a sequential circuit model 756. The model transformation step 757 is to convert the sequential circuit model 756 into an equivalent combinational circuit model 758. The pseudo-random pattern fault simulation step 759 is to identify the faults that are detected by a set of pseudo-random patterns. Finally, the post-processing step 760 is to generate HDL test benches and ATE (automatic test equipment) test programs 761. All reports and errors are stored in the report files 762.

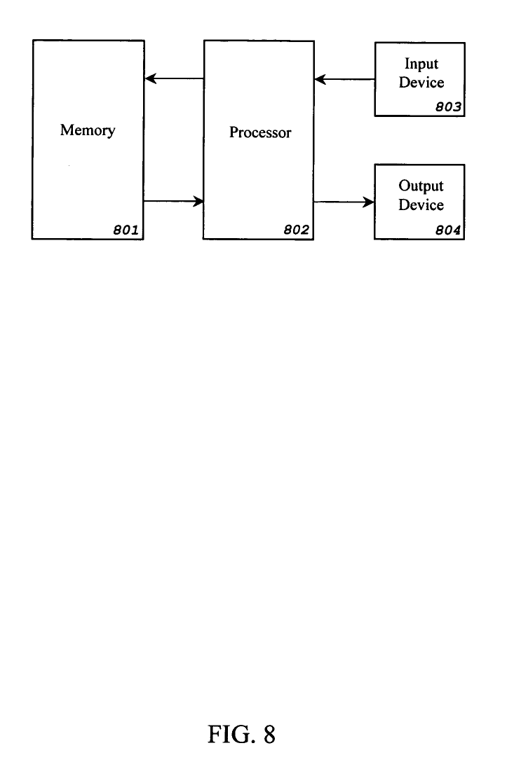

FIG. 8 shows an example electronic design automation system 800 in which the method for repairing asynchronous set/reset violations at either RTL (register-transfer level) or gate-level and the method of generating test patterns for data faults and set/reset faults, in accordance with the present invention, may be implemented. The system 800 includes a processor 802, which operates together with a memory 801 to run a set of the asynchronous set/reset repair and test pattern generation software. The processor 802 may represent a central processing unit of a personal computer, workstation, mainframe computer or other suitable digital processing device. The memory 801 can be an electronic memory or a magnetic or optical disk-based memory, or various combinations thereof. A designer interacts with the asynchronous set/reset repair and test pattern generation software run by the processor 802 to provide appropriate inputs via an input device 803, which may be a keyboard, disk drive or other suitable source of design information. The processor 802 provides outputs to the designer via an output device 804, which may be a display, a printer, a disk drive or various combinations of these and other elements.

Having thus described presently preferred embodiments of the present invention, it can now be appreciated that the objectives of the invention have been fully achieved. And it will be understood by those skilled in the art that many changes in construction & circuitry, and widely differing embodiments & applications of the invention will suggest themselves without departing from the spirit and scope of the present invention. The disclosures and the description herein are intended to be illustrative and are not in any sense limitation of the invention, more preferably defined in scope by the following claims.

What is claimed is:

1. A method for testing faults propagated to the data ports and asynchronous set/reset ports of selected scan cells in a scan-based integrated circuit in a selected scan-test mode or selected self-test mode, the scan-based integrated circuit containing a plurality of set/reset circuitries, a plurality of set/reset controllers, and a plurality of scan chains, each scan chain comprising multiple scan cells coupled in series, each scan cell having one or more clocks and each set/reset controller having a scan enable (SE) signal and a set/reset enable (SR_EN) signal; said method comprising:
(a) shifting in a stimulus to all said scan cells in said scan-based integrated circuit by enabling all said scan enable (SE) signals connected to all said scan cells during a shift-in operation;
(b) capturing a test response of all said scan cells for testing said faults propagated to said data ports and said asynchronous set/reset ports of all said selected scan cells by enabling or disabling all said set/reset enable (SR_EN) signals connected to all said selected scan cells during a capture operation;
(c) shifting out said test response for comparison or compaction while shifting in a new stimulus to all said scan cells during a shift-out operation; and
(d) repeating steps (b) to (c) until a limiting criteria is reached.

2. The method of claim 1, wherein said shifting in a stimulus to all said scan cells further comprises selectively shifting in a predetermined stimulus from an ATE (automatic test equipment) in said selected scan-test mode or shifting in a pseudo-random stimulus automatically generated in said scan-based integrated circuit using a pseudo-random pattern generator (PRPG) in said selected self-test mode during said shift-in operation.

3. The method of claim 1, wherein said shifting in a stimulus to all said scan cells further comprises using all said set/reset enable (SR_EN) signals to disable all said asynchronous set/reset ports of all said selected scan cells during said shift-in operation.

4. The method of claim 1, wherein said capturing a test response of all said scan cells further comprises selectively disabling all said scan enable (SE) signals simultaneously or in an ordered sequence during said capture operation.

5. The method of claim 1, wherein said capturing a test response of all said scan cells further comprises disabling all said clocks controlling all said scan cells, while enabling all said set/reset enable (SR_EN) signals, for testing said faults propagated to said asynchronous set/reset ports of all said selected scan cells during said capture operation.

6. The method of claim 5, wherein said enabling all said set/reset enable (SR_EN) signals further comprises selectively enabling two or more said set/reset enable (SR_EN) signals simultaneously or in an ordered sequence during said capture operation.

7. The method of claim 1, wherein said capturing a test response of all said scan cells further comprises enabling all said clocks controlling all said scan cells, while disabling all said set/reset enable (SR_EN) signals, for testing said faults propagated to said data ports of all said selected scan cells during said capture operation.

8. The method of claim 7, wherein said enabling all said clocks controlling all said scan cells further comprises selectively enabling two or more said clocks controlling two or more said scan cells simultaneously or in an ordered sequence during said capture operation.

9. The method of claim 1, wherein said shifting out said test response for comparison or compaction further comprises selectively shifting out said test response to said ATE for comparison in said selected scan-test mode or shifting out said test response for compaction using a compactor, including a multiple-input signature register (MISR), in said selected self-test mode during said shift-out operation.

10. The method of claim 1, wherein said set/reset controller further comprises providing a shift controller and a capture controller in response to a said scan enable (SE) signal and a said set/reset enable (SR_EN) signal, wherein said shift controller is adapted to disable said asynchronous set/reset ports of one or more said selected scan cells during said shift-in or said shift-out operation, and wherein said capture controller is adapted to enable or disable propagation of said faults present in one said set/reset circuitry to said asynchronous set/reset ports of one or more said selected scan cells during said capture operation.

11. The method of claim 1, wherein said scan enable (SE) signal is selectively generated in said scan-based integrated circuit or an input signal to said scan-based integrated circuit.

12. The method of claim 11, wherein all said scan enable (SE) signals are further driven by one or more global scan enable (global_SE) signals, wherein each said global scan enable (global_SE) signal is selectively generated in said scan-based integrated circuit or an input signal to said scan-based integrated circuit.

13. The method of claim 1, wherein said set/reset enable (SR_EN) signal is selectively generated in said scan-based integrated circuit or an input signal to said scan-based integrated circuit.

14. The method of claim 13, wherein all set/reset enable (SR_EN) signals are further driven by one or more global set/reset enable (global_SR_EN) signals, wherein each said global set/reset enable (global_SR_EN) signal is selectively generated in said scan-based integrated circuit or an input signal to said scan-based integrated circuit.

15. The method of claim 1, wherein said scan cell is a multiplexed-type D flip-flop, a two-port D flip-flop, or a LSSD (level-sensitive scan design) SRL (shift register latch).

16. The method of claim 1, wherein said set/reset controller is used to repair one or more asynchronous set/reset violations, comprising sequentially-gated set/reset violations, combinationally-gated set/reset violations, generated set/reset violations, and destructive set/reset violations, in a selected set/reset circuitry in said scan-based integrated circuit.

17. A set/reset controller having a scan enable (SE) signal and a set/reset enable (SR_EN) signal for testing faults propagated to the data ports and asynchronous set/reset ports of selected scan cells in a scan-based integrated circuit, the scan-based integrated circuit containing a plurality of set/reset circuitries and a plurality of scan chains, each scan chain comprising multiple scan cells coupled in series, each scan cell having one or more clocks; said set/reset controller comprising:
(a) a shift controller, inserted between a selected set/reset circuitry and said asynchronous set/reset ports of all said selected scan cells, for disabling said asynchronous set/reset ports of all said selected scan cells, in response to said scan enable (SE) signal and said set/reset enable (SR_EN) signal, during a shift-in or shift-out operation; and
(b) a capture controller, inserted between said selected set/reset circuitry and said asynchronous set/reset ports of all said selected scan cells, for enabling or disabling propagation of said faults present in said selected set/reset circuitry to said asynchronous set/reset ports of all said selected scan cells, in response to said scan enable (SE) signal and said set/reset enable (SR_EN) signal, during a capture operation.

18. The set/reset controller of claim 17, wherein said shift controller is selectively embedded in said selected set/reset circuitry or in all said selected scan cells, and wherein said enable (SE) signal, said set/reset enable (SR_EN) signal, or said scan enable (SE) signal and said set/reset enable (SR_EN) signal can be selectively used to disable all said asynchronous set/reset ports of all said selected scan cells during said shift-in or shift-out operation.

19. The set/reset controller of claim 17, wherein said capture controller further comprises selectively disabling all said scan enable (SE) signals simultaneously or in an ordered sequence during said capture operation.

20. The set/reset controller of claim 17, wherein said capture controller further comprises disabling all said clocks controlling all said scan cells, while enabling all said set/reset enable (SR_EN) signals, for testing said faults propagated to said asynchronous set/reset ports of all said selected scan cells during said capture operation.

21. The set/reset controller of claim 20, wherein said enabling all said set/reset enable (SR_EN) signals further comprises selectively enabling two or more said set/reset enable (SR_EN) signals simultaneously or in an ordered sequence during said capture operation.

22. The set/reset controller of claim 17, wherein said capture controller further comprises enabling all said clocks controlling all said scan cells, while disabling all said set/reset enable (SR_EN) signals, for testing said faults propagated to said data ports of all said selected scan cells during said capture operation.

23. The set/reset controller of claim 22, wherein said enabling all said clocks controlling all said scan cells further comprises selectively enabling two or more said clocks controlling two or more said scan cells simultaneously or in an ordered sequence during said capture operation.

24. The set/reset controller of claim 17, wherein said capture controller is selectively embedded in said selected set/reset circuitry or in all said selected scan cells.

25. The set/reset controller of claim 17, wherein said scan enable (SE) signal is selectively generated in said scan-based integrated circuit or an input signal to said scan-based integrated circuit.

26. The set/reset controller of claim 25, wherein all said scan enable (SE) signals are further driven by one or more global scan enable (global_SE) signals, wherein each said global scan enable (global_SE) signal is selectively generated in said scan-based integrated circuit or an input signal to said scan-based integrated circuit.

27. The set/reset controller of claim 17, wherein said set/reset enable (SR_EN) signal is selectively generated in said scan-based integrated circuit or an input signal to said scan-based integrated circuit.

28. The set/reset controller of claim 27, wherein all set/reset enable (SR_EN) signals are further driven by one or more global set/reset enable (global_SR_EN) signals, wherein each said global set/reset enable (global_SR_EN) signal is selectively generated in said scan-based integrated circuit or an input signal to said scan-based integrated circuit.

29. The set/reset controller of claim 17, wherein said scan cell is a multiplexed-type D flip-flop, a two-port D flip-flop, or a LSSD (level-sensitive scan design) SRL (shift register latch).

30. The set/reset controller of claim 17, wherein said shift controller and capture controller are used to repair one or more asynchronous set/reset violations, comprising sequentially-gated set/reset violations, combinationally-gated set/reset violations, generated set/reset violations, and destructive set/reset violations, in said selected set/reset circuitry in said scan-based integrated circuit.

31. A method for synthesizing a plurality of set/reset controllers each having a scan enable (SE) signal and a set/reset enable (SR_EN) signal for testing faults propagated to the data ports and asynchronous set/reset ports of selected scan cells in a scan-based integrated circuit, the scan-based integrated circuit containing a plurality of set/reset circuitries and a plurality of scan chains, each scan chain comprising multiple scan cells coupled in series, each scan cell having one or more clocks; said method comprising the computer-implemented steps of:
(a) compiling the HDL (hardware description language) code modeled at RTL (register-transfer level) or gate-level that represents said scan-based integrated circuit into a sequential circuit model;
(b) specifying a list of asynchronous set/reset signals each causing one or more asynchronous set/reset violations in each selected set/reset circuitry for repair;
(c) synthesizing a said plurality of set/reset controllers, each having a said scan enable (SE) signal and a said set/reset enable (SR_EN) signal, on said sequential circuit model according to said list of asynchronous set/reset signals; and
(d) generating the repaired HDL code in a selected RTL or gate-level format.

32. The method of claim 32, wherein said specifying a list of asynchronous set/reset signals further comprises automatically identifying said list of asynchronous set/reset signals using simulation methods.

33. The method of claim 32, wherein said set/reset controller in said synthesizing a said plurality of set/reset controllers further comprises
(e) a shift controller, inserted between said selected set/reset circuitry and said asynchronous set/reset ports of all said selected scan cells, for disabling said asynchronous set/reset ports of all said selected scan cells, in response to said scan enable (SE) signal and said set/reset enable (SR_EN) signal, during a shift-in or shift-out operation; and
(f) a capture controller, inserted between said selected set/reset circuitry and said asynchronous set/reset ports of all said selected scan cells, for enabling or disabling propagation of said faults present in said selected set/reset circuitry to said asynchronous set/reset ports of one or more said selected scan cells, in response to said scan enable (SE) signal and said set/reset enable (SR_EN) signal, during a capture operation.

34. The method of claim 33, wherein said shift controller is selectively embedded in said selected set/reset circuitry or in one or more said selected scan cells, and wherein said enable (SE) signal, said set/reset enable (SR_EN) signal, or said scan enable (SE) signal and said set/reset enable (SR_EN) signal can be selectively used to disable all said asynchronous set/reset ports of all said selected scan cells during said shift-in or said shift-out operation.

35. The method of claim 33, wherein said capture controller further comprises selectively disabling all said scan enable (SE) signals simultaneously or in an ordered sequence during said capture operation.

36. The method of claim 33, wherein said capture controller further comprises disabling all said clocks controlling all said scan cells, while enabling all said set/reset enable (SR_EN) signals, for testing said faults propagated to said asynchronous set/reset ports of one or more said selected scan cells during said capture operation.

37. The method of claim 36, wherein said enabling all said set/reset enable (SR_EN) signals further comprises selectively enabling two or more said set/reset enable (SR_EN) signals simultaneously or in an ordered sequence during said capture operation.

38. The method of claim 33, wherein said capture controller further comprises enabling all said clocks controlling all said scan cells, while disabling all said set/reset enable (SR_EN) signals, for testing said faults propagated to said data ports of all said selected scan cells during said capture operation.

39. The method of claim 38, wherein said enabling all said clocks controlling all said scan cells further comprises selectively enabling two or more said clocks controlling two or more said selected scan cells simultaneously or in an ordered sequence during said capture operation.

40. The method of claim 33, wherein said capture controller is selectively embedded in said selected set/reset circuitry or in said selected scan cells.

41. The method of claim 33, wherein said scan enable (SE) signal is selectively generated in said scan-based integrated circuit or an input signal to said scan-based integrated circuit.

42. The method of claim 41, wherein all said scan enable (SE) signals are further driven by one or more global scan enable (global_SE) signals, wherein each said global scan enable (global_SE) signal is selectively generated in said scan-based integrated circuit or an input signal to said scan-based integrated circuit.

43. The method of claim 33, wherein said set/reset enable (SR_EN) signal is selectively generated in said scan-based integrated circuit or an input signal to said scan-based integrated circuit.

44. The method of claim 43, wherein all set/reset enable (SR_EN) signals are further driven by one or more global set/reset enable (global_SR_EN) signals, wherein each said global set/reset enable (global_SR_EN) signal is selectively generated in said scan-based integrated circuit or an input signal to said scan-based integrated circuit.

45. The method of claim 33, wherein said scan cell is a multiplexed-type D flip-flop, a two-port D flip-flop, or a LSSD (level-sensitive scan design) SRL (shift register latch).

46. The method of claim 33, wherein said shift controller and capture controller are used to repair one or more asynchronous set/reset violations, comprising sequentially-gated set/reset violations, combinationally-gated set/reset violations, generated set/reset violations, and destructive set/reset violations, in said selected set/reset circuitry in said scan-based integrated circuit.

47. A method for generating stimuli and test responses for testing faults propagated to the data ports and asynchronous set/reset ports of selected scan cells in a scan-based integrated circuit in a selected scan-test mode or selected self-test mode, the scan-based integrated circuit containing a plurality of set/reset circuitries, a plurality of set/reset controllers, and a plurality of scan chains, each scan chain comprising multiple scan cells coupled in series, each scan cell having one or more clocks and each set/reset controller having a scan enable (SE) signal and a set/reset enable (SR_EN) signal; said method comprising the computer-implemented steps of:
(a) compiling the HDL (hardware description language) code modeled at RTL (register-transfer level) or gate-level that represents said scan-based integrated circuit into a sequential circuit model;
(b) specifying input constraints on said clocks, said scan enable (SE) signals, and said set/reset enable (SR_EN) signals during a shift-in, capture, or shift-out operation;
(c) transforming said sequential circuit model into an equivalent combinational circuit model; and
(d) generating said stimuli and said test responses according to said input constraints and said combinational circuit model.

48. The method of claim 47, wherein said specifying input constraints on said clocks, said scan enable (SE) signals, and said set/reset enable (SR_EN) signals further comprises setting all said set/reset enable (SR_EN) signals to logic value 1 to disable all said asynchronous set/reset ports of all said selected scan cells during said shift-in or said shift-out operation.

49. The method of claim 47, wherein said specifying input constraints on said clocks, said scan enable (SE) signals, and said set/reset enable (SR_EN) signals further comprises setting all said scan enable (SE) signals to logic value 1 to disable all said asynchronous set/reset ports of all said selected scan cells during said shift-in or said shift-out operation.

50. The method of claim 47, wherein specifying input constraints on said clocks, said scan enable (SE) signals, and said set/reset enable (SR_EN) signals further comprises selectively setting all said scan enable (SE) signals to logic value 0 simultaneously or in an ordered sequence during said capture operation.

51. The method of claim 47, wherein specifying input constraints on said clocks, said scan enable (SE) signals, and said set/reset enable (SR_EN) signals further comprises setting all said clocks controlling all said scan cells to logic value 0, while setting all said set/reset enable (SR_EN) signals to logic value 1, for testing said faults propagated to said asynchronous set/reset ports of all said selected scan cells during said capture operation.

52. The method of claim 51, wherein said setting all said set/reset enable (SR_EN) signals to logic value 1 further comprises selectively setting two or more said set/reset enable (SR_EN) signals to logic value 1 simultaneously or in an ordered sequence during said capture operation.

53. The method of claim 47, wherein specifying input constraints on said clocks, said scan enable (SE) signals, and said set/reset enable (SR_EN) signals further comprises setting all said clocks controlling all said scan cells to logic value 1, while setting all said set/reset enable (SR_EN) signals to logic value 0, for testing said faults propagated to said data ports of all said selected scan cells during said capture operation.

54. The method of claim 53, wherein said setting all said clocks controlling all said scan cells to logic value 1 further comprises selectively setting two or more said clocks controlling two or more said scan cells to logic value 1 simultaneously or in an ordered sequence during said capture operation.

55. The method of claim 47, wherein said generating said stimuli and said test responses according to said input constraints and said combinational circuit model further comprises performing fault simulation on said combinational circuit model using a selected set of predetermined patterns in said selected scan-test mode or a selected set of pseudo-random patterns in said selected self-test mode.

56. The method of claim 47, wherein said generating said stimuli and said test responses according to said input constraints and said combinational circuit model further comprises performing combinational ATPG (automatic test pattern generation) on said combinational circuit model to generate said stimuli and said test responses in said selected scan-test mode.

57. The method of claim 47, wherein said generating said stimuli and said test responses according to said input constraints and said combinational circuit model further comprises generating HDL test benches according to said stimuli and said test responses for verifying the correctness of said scan-based integrated circuit using simulation methods.

58. The method of claim 47, wherein said generating said stimuli and said test responses according to said input constraints and said combinational circuit model further comprises generating ATE (automatic test equipment) test programs according to said stimuli and said test responses for verifying the correctness of said scan-based integrated circuit in said ATE.

59. A computer-readable memory having computer-readable program code embodied therein for causing a computer system to perform a method for generating stimuli and test responses for testing faults propagated to the data ports and asynchronous set/reset ports of selected scan cells in a scan-based integrated circuit in a selected scan-test mode or selected self-test mode, the scan-based integrated circuit containing a plurality of set/reset circuitries, a plurality of set/reset controllers, and a plurality of scan chains, each scan chain comprising multiple scan cells coupled in series, each scan cell having one or more clocks and each set/reset controller having a scan enable (SE) signal and a set/reset enable (SR_EN) signal; said method comprising the computer-implemented steps of:
(a) compiling the HDL (hardware description language) code modeled at RTL (register-transfer level) or gate-level that represents said scan-based integrated circuit into a sequential circuit model;
(b) specifying input constraints on said clocks, said scan enable (SE) signals, and said set/reset enable (SR_EN) signals during a shift-in, capture, or shift-out operation;
(c) transforming said sequential circuit model into an equivalent combinational circuit model; and
(d) generating said stimuli and said test responses according to said input constraints and said combinational circuit model.

60. The computer-readable memory of claim 59, wherein said specifying input constraints on said clocks, said scan enable (SE) signals, and said set/reset enable (SR_EN) signals further comprises setting all said set/reset enable (SR_EN) signals to logic value 1 to disable all said asynchronous set/reset ports of all said selected scan cells during said shift-in or said shift-out operation.

61. The computer-readable memory of claim 59, wherein said specifying input constraints on said clocks, said scan enable (SE) signals, and said set/reset enable (SR_EN) signals further comprises setting all said scan enable (SE) signals to logic value 1 to disable all said asynchronous set/reset ports of all said selected scan cells during said shift-in or said shift-out operation.

62. The computer-readable memory of claim 59, wherein specifying input constraints on said clocks, said scan enable (SE) signals, and said set/reset enable (SR_EN) signals further comprises selectively setting all said scan enable (SE) signals to logic value 0 simultaneously or in an ordered sequence during said capture operation.

63. The computer-readable memory of claim 59, wherein specifying input constraints on said clocks, said scan enable (SE) signals, and said set/reset enable (SR_EN) signals further comprises setting all said clocks controlling all said scan cells to logic value 0, while setting all said set/reset enable (SR_EN) signals to logic value 1, for testing said faults propagated to said asynchronous set/reset ports of all said selected scan cells during said capture operation.

64. The computer-readable memory of claim 63, wherein said setting all said set/reset enable (SR_EN) signals to logic value 1 further comprises selectively setting two or more said set/reset enable (SR_EN) signals to logic value 1 simultaneously or in an ordered sequence during said capture operation.

65. The computer-readable memory of claim 59, wherein specifying input constraints on said clocks, said scan enable (SE) signals, and said set/reset enable (SR_EN) signals further comprises setting all said clocks controlling all said scan cells to logic value 1, while setting all said set/reset enable (SR_EN) signals to logic value 0, for testing said faults propagated to said data ports of all said selected scan cells during said capture operation.

66. The computer-readable memory of claim 65, wherein said setting all said clocks controlling all said scan cells to logic value 1 further comprises selectively setting two or more said clocks controlling two or more said scan cells to logic value 1 simultaneously or in an ordered sequence during said capture operation.

67. The computer-readable memory of claim 59, wherein said generating said stimuli and said test responses according to said input constraints and said combinational circuit model further comprises performing fault simulation on said combinational circuit model using a selected set of predetermined patterns in said selected scan-test mode or a selected set of pseudo-random patterns in said selected self-test mode.

68. The computer-readable memory of claim 59, wherein said generating said stimuli and said test responses according to said input constraints and said combinational circuit model further comprises performing combinational ATPG (automatic test pattern generation) on said combinational circuit model to generate said stimuli and said test responses in said selected scan-test mode.

69. The computer-readable memory of claim 59, wherein said generating said stimuli and said test responses according to said input constraints and said combinational circuit model further comprises generating HDL test benches according to said stimuli and said test responses for verifying the correctness of said scan-based integrated circuit using simulation methods.

70. The computer-readable memory of claim 59, wherein said generating said stimuli and said test responses according to said input constraints and said combinational circuit model further comprises generating ATE (automatic test equipment) test programs according to said stimuli and said test responses for verifying the correctness of said scan-based integrated circuit in said ATE.

71. An electronic design automation system comprising: a processor; a bus coupled to said processor; and a computer-readable memory coupled to said bus and having computer-readable program code stored therein for causing said electronic design automation system to perform a method for generating stimuli and test responses for testing faults propagated to the data ports and asynchronous set/reset ports of selected scan cells in a scan-based integrated circuit in a selected scan-test mode or selected self-test mode, the scan-based integrated circuit containing a plurality of set/reset circuitries, a plurality of set/reset controllers, and a plurality of scan chains, each scan chain comprising multiple scan cells coupled in series, each scan cell having one or more clocks and each set/reset controller having a scan enable (SE) signal and a set/reset enable (SR_EN) signal; said method comprising the computer-implemented steps of:
(a) compiling the HDL (hardware description language) code modeled at RTL (register-transfer level) or gate-level that represents said scan-based integrated circuit into a sequential circuit model;
(b) specifying input constraints on said clocks, said scan enable (SE) signals, and said set/reset enable (SR_EN) signals during a shift-in, capture, or shift-out operation;
(c) transforming said sequential circuit model into an equivalent combinational circuit model; and
(d) generating said stimuli and said test responses according to said input constraints and said combinational circuit model.

72. The system of claim 71, wherein said specifying input constraints on said clocks, said scan enable (SE) signals, and said set/reset enable (SR_EN) signals further comprises setting all said set/reset enable (SR_EN) signals to logic value 1 to disable all said asynchronous set/reset ports of all said selected scan cells during said shift-in or said shift-out operation.

73. The system of claim 71, wherein said specifying input constraints on said clocks, said scan enable (SE) signals, and said set/reset enable (SR_EN) signals further comprises setting all said scan enable (SE) signals to logic value 1 to disable all said asynchronous set/reset ports of all said selected scan cells during said shift-in or said shift-out operation.

74. The system of claim 71, wherein specifying input constraints on said clocks, said scan enable (SE) signals, and said set/reset enable (SR_EN) signals further comprises selectively setting all said scan enable (SE) signals to logic value 0 simultaneously or in an ordered sequence during said capture operation.

75. The system of claim 71, wherein specifying input constraints on said clocks, said scan enable (SE) signals, and said set/reset enable (SR_EN) signals further comprises setting all said clocks controlling all said scan cells to logic value 0, while setting all said set/reset enable (SR_EN) signals to logic value 1, for testing said faults propagated to said asynchronous set/reset ports of all said selected scan cells during said capture operation.

76. The system of claim 75, wherein said setting all said set/reset enable (SR_EN) signals to logic value 1 further comprises selectively setting two or more said set/reset enable (SR_EN) signals to logic value 1 simultaneously or in an ordered sequence during said capture operation.

77. The system of claim 71, wherein specifying input constraints on said clocks, said scan enable (SE) signals, and said set/reset enable (SR_EN) signals further comprises setting all said clocks controlling all said scan cells to logic value 1, while setting all said set/reset enable (SR_EN) signals to logic value 0, for testing said faults propagated to said data ports of all said selected scan cells during said capture operation.

78. The system of claim 77, wherein said setting all said clocks controlling all said scan cells to logic value 1 further comprises selectively setting two or more said clocks controlling two or more said scan cells to logic value 1 simultaneously or in an ordered sequence during said capture operation.

79. The system of claim 71, wherein said generating said stimuli and said test responses according to said input constraints and said combinational circuit model further comprises performing fault simulation on said combinational circuit model using a selected set of predetermined patterns in said selected scan-test mode or a selected set of pseudo-random patterns in said selected self-test mode.

80. The system of claim 71, wherein said generating said stimuli and said test responses according to said input constraints and said combinational circuit model further comprises performing combinational ATPG (automatic test pattern generation) on said combinational circuit model to generate said stimuli and said test responses in said selected scan-test mode.

81. The system of claim 71, wherein said generating said stimuli and said test responses according to said input constraints and said combinational circuit model further comprises generating HDL test benches according to said stimuli and said test responses for verifying the correctness of said scan-based integrated circuit using simulation methods.

82. The system of claim 71, wherein said generating said stimuli and said test responses according to said input constraints and said combinational circuit model further comprises generating ATE (automatic test equipment) test programs according to said stimuli and said test responses for verifying the correctness of said scan-based integrated circuit in said ATE.
